(19) United States
(12) Patent Application Publication
(10) Pub. No.: US 2026/0068453 A1
(43) Pub. Date: Mar. 5, 2026

(54) DISPLAY APPARATUS, ELECTRONIC APPARATUS INCLUDING DISPLAY APPARATUS, AND METHOD OF MANUFACTURING DISPLAY APPARATUS

(71) Applicant: Samsung Display Co., Ltd., Yongin-Si (KR)

(72) Inventors: Sungeun Lee, Yongin-si (KR); Kinyeng Kang, Yongin-si (KR); Chanju Park, Yongin-si (KR); Hyoengki Kim, Yongin-si (KR); Keunkyu Song, Yongin-si (KR)

(21) Appl. No.: 19/046,521

(22) Filed: Feb. 6, 2025

(30) Foreign Application Priority Data
Aug. 28, 2024 (KR) 10-2024-0115971

(51) Int. Cl. H10K 59/131; H10K 50/19; H10K 59/12; H10K 59/122

(52) U.S. Cl. CPC H10K 59/131; H10K 59/1201; H10K 59/122; H10K 50/19

(57) ABSTRACT

Provided is a display apparatus including a substrate, a first pixel electrode and a second electrode arranged apart from each other over the substrate, a first bank layer disposed on the first pixel electrode and the second electrode and including a first-1 opening above the first pixel electrode, and a second-1 opening above the second pixel electrode, a second bank layer disposed on the first bank layer and including a first-2 opening above the first pixel electrode, and a second-2 opening above the second pixel electrode, and a wiring layer disposed on the second bank layer and including a portion disposed between the first pixel electrode and the second pixel electrode, wherein the first bank layer includes a first inorganic insulating material and the second bank layer includes a second inorganic insulating material having a different selectivity than the first inorganic insulating material.

### CROSS-REFERENCE TO RELATED APPLICATION

This application is based on and claims priority, under 35 U.S.C. § 119, to Korean Patent Application No. 10-2024-0115971 filed on Aug. 28, 2024 in the Korean Intellectual Property Office, the disclosure of which is incorporated by reference herein in its entirety.

### BACKGROUND

### 1. Field

One or more embodiments relate to an apparatus and a method, and more particularly, to a display apparatus, an electronic apparatus, and a method of manufacturing a display apparatus.

### 2. Description of the Related Art

Mobile electronic apparatuses are widely used. As mobile electronic apparatuses, recently, tablet personal computers (PCs) have been widely used as well as miniaturized electronic apparatuses such as mobile phones.

To support various functions, for example, to provide a user with visual information such as images, such mobile electronic apparatuses include a display apparatus. Recently, as the parts configured to drive a display apparatus have been miniaturized, the proportion taken up by a display apparatus has gradually increased. As demand for more display space increases, structures that may be bent to a preset angle from a flat state are also under development.

### SUMMARY

One or more embodiments include a display apparatus with a reduced leakage current between a plurality of pixels.

One or more embodiments include a method of manufacturing a display apparatus with a reduced number of deposition masks to form a structure of a display apparatus with a reduced leakage current.

However, such technical objectives are just examples, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, a first pixel electrode and a second electrode arranged apart from each other over the substrate, a first bank layer disposed on the first pixel electrode and the second electrode and including a first-1 opening above the first pixel electrode, and a second-1 opening above the second pixel electrode, a second bank layer disposed on the first bank layer and including a first-2 opening above the first pixel electrode, and a second-2 opening above the second pixel electrode, and a wiring layer disposed on the second bank layer and including a portion disposed between the first pixel electrode and the second pixel electrode, wherein the first bank layer includes a first inorganic insulating material and the second bank layer includes a second inorganic insulating material having a different selectivity from the first inorganic insulating material.

In an embodiment, the display apparatus may further include a first-1 intermediate layer disposed on the first pixel electrode, a first charge generation layer disposed on the first-1 intermediate layer, a first-2 intermediate layer disposed on the first charge generation layer, a second-1 intermediate layer disposed on the second pixel electrode, a second charge generation layer disposed on the second-1 intermediate layer, a second-2 intermediate layer disposed on the second charge generation layer, and an opposite electrode disposed on the first-2 intermediate layer and the second-2 intermediate layer.

In an embodiment, the wiring layer may be electrically connected to the opposite electrode.

In an embodiment, the opposite electrode may be electrically connected to a common voltage supply line.

In an embodiment, the display apparatus may include a display area and a peripheral area, and the wiring layer may be in direct contact with the opposite electrode near a border between the display area and the peripheral area within the display area.

In an embodiment, the first-1 intermediate layer and the second-1 intermediate layer may be separated from each other.

In an embodiment, in a plan view, the wiring layer may have a mesh structure including a hole above the first pixel electrode, and a hole above the second pixel electrode.

In an embodiment, a size of the first-1 opening may be greater than a size of the first-2 opening, and a size of the second-1 opening may be greater than a size of the second-2 opening.

The first bank layer and the second bank layer may form an undercut structure where the second bank layer extends beyond the edge of the first bank layer.

According to one or more embodiments, an electronic apparatus including a display apparatus and a housing accommodating the display apparatus, wherein the display apparatus includes a substrate, a first pixel electrode and a second electrode arranged apart from each other over the substrate, a first bank layer disposed on the first pixel electrode and the second electrode and including a first-1 opening above the first pixel electrode, and a second-1 opening above the second pixel electrode, a second bank layer disposed on the first bank layer and including a first-2 opening above the first pixel electrode, and a second-2 opening above the second pixel electrode, and a wiring layer disposed on the second bank layer and including a portion disposed between the first pixel electrode and the second pixel electrode, wherein the first bank layer includes a first inorganic insulating material and the second bank layer includes a second inorganic insulating material having a different selectivity from the first inorganic insulating material.

According to one or more embodiments, a method of manufacturing a display apparatus includes, providing a substrate including a display area and a peripheral area, arranging a first pixel electrode and a second pixel electrode in the display area, sequentially arranging a first layer, a second layer, and a third layer on the first pixel electrode and the second pixel electrode, and patterning the first layer, the second layer, and the third layer to form a first bank layer, a second bank layer, and a wiring layer, respectively, to expose a central portion of the first pixel electrode and a central portion of the second pixel electrode, wherein the first layer includes a first inorganic insulating material and the second layer includes a second inorganic insulating material having a different selectivity from the first inorganic insulating material, and the third layer includes a conductive material.

In an embodiment, the patterning may include arranging a photoresist on the third layer, patterning the third layer, and patterning the first layer and the second layer after the patterning of the third layer.

In an embodiment, the patterning of the third layer may include forming the wiring layer having a mesh structure including a hole above the first pixel electrode and a hole above the second pixel electrode.

In an embodiment, the second patterning may include patterning the first layer such that the first bank layer has a first-1 opening above the first pixel electrode and a second-1 opening above the second pixel electrode, and patterning the second layer such that the second bank layer has a first-2 opening above the first pixel electrode and a second-2 opening above the second pixel electrode.

In an embodiment, a size of the first-1 opening may be greater than a size of the first-2 opening, and a size of the second-1 opening may be greater than a size of the second-2 opening.

In an embodiment, the patterning of the first layer and the second layer may include removing a portion of the first layer and a portion of the second layer disposed in the peripheral area.

In an embodiment, the method may further include arranging a first-1 intermediate layer on the first pixel electrode, arranging a second-1 intermediate layer on the second pixel electrode, arranging a charge generation layer on the first-1 intermediate layer and the second-1 intermediate layer, arranging a first-2 intermediate layer on the charge generation layer and on the first pixel electrode, and arranging a second-2 intermediate layer on the charge generation layer and on the second pixel electrode.

In an embodiment, the first-1 intermediate layer and the second-1 intermediate layer may be separated from each other.

In an embodiment, the method may further include arranging an opposite electrode on the first-2 intermediate layer and the second-2 intermediate layer, wherein the wiring layer may be in direct contact with the opposite electrode, near a border between the display area and the peripheral area, within the display area.

In an embodiment, the opposite electrode may be connected to a common voltage supply line in the peripheral area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of an electronic apparatus according to an embodiment;

FIG. 2 is a schematic plan view of a display apparatus according to an embodiment;

FIG. 3 is a schematic circuit diagram of a light-emitting diode provided in a pixel of a display apparatus and a pixel circuit connected to the light-emitting diode, according to an embodiment;

FIG. 4 is a schematic plan view of a portion of a display apparatus according to an embodiment;

FIG. 5 is a schematic cross-sectional view of a portion of a display apparatus according to an embodiment;

FIG. 6 is a schematic cross-sectional view of a portion of a display apparatus according to an embodiment; and

FIGS. 7A, 7B, 7C, 7D, 7E, 7F, 7G, 7H, 7I, and 7J are schematic cross-sectional views showing processes of a method of manufacturing a display apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to any order or priority by the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. For example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. For example, two processes successively described may be simultaneously performed substantially and performed in the opposite order.

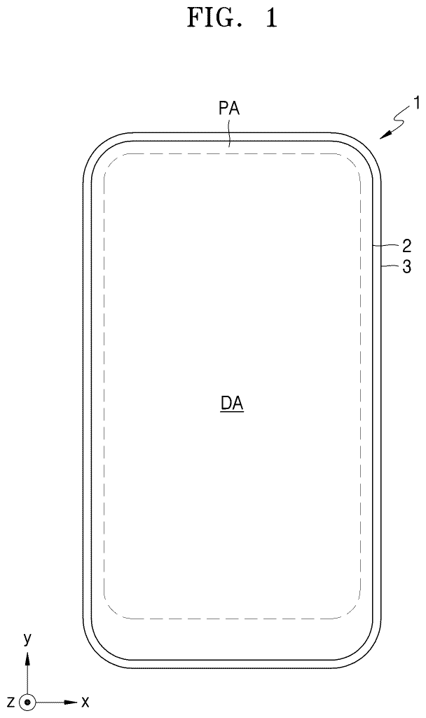

FIG. 1 is a schematic plan view of an electronic apparatus 1 according to an embodiment.

The electronic apparatus 1 may include a display apparatus 2 and a housing 3. In an embodiment, the display apparatus 2 may be accommodated in the housing 3.

The electronic apparatus 1 may include various products including televisions, notebook computers, monitors, advertisement boards, Internet of things (IoTs) apparatuses as well as portable electronic apparatuses including mobile phones, smartphones, tablet personal computers (PCs), mobile communication terminals, electronic organizers, electronic books, portable multimedia players (PMPs), navigations, and ultra mobile personal computers (UMPCs). In addition, the electronic apparatus 1 according to an embodiment may include wearable devices including smartwatches, watchphones, glasses-type displays, and head-mounted displays (HMDs). In addition, in an embodiment, the electronic apparatus 1 is applicable to a display screen in instrument panels for automobiles, center fascias for automobiles, or center information displays (CIDs) arranged on a dashboard, room mirror displays that replace side mirrors of automobiles, and displays of an entertainment system arranged on the backside of front seats for backseat passengers in automobiles. The display apparatus 2 is an element displaying moving images or still images in various embodiments of the electronic apparatus 1 and may be included in the electronic apparatus 1.

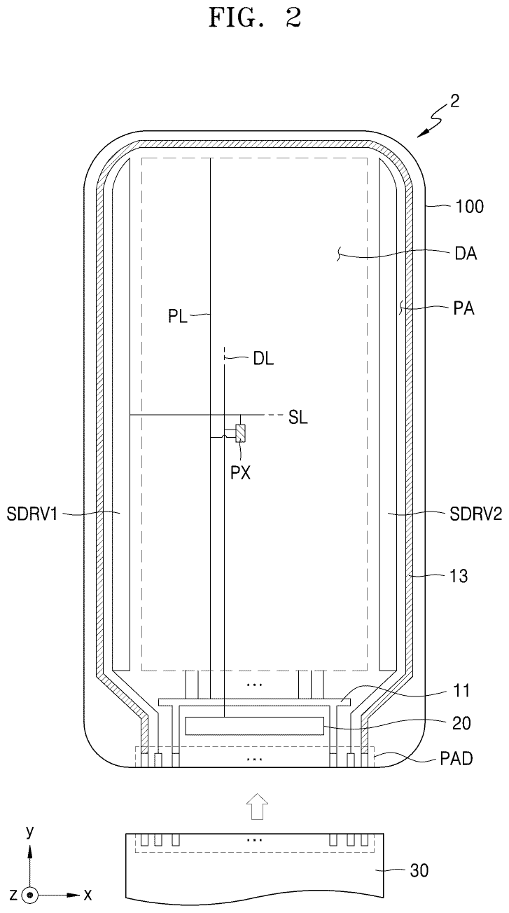

The display apparatus 2 may include a display area DA and a peripheral area PA outside the display area DA. Because the display apparatus 2 includes a substrate 100 (see FIG. 2), it may be understood that the substrate 100 includes the display area DA and the peripheral area PA. Alternatively, it may be understood that the display area DA and the peripheral area PA are defined in the substrate 100.

The display area DA is a region in which images are displayed, and a plurality of pixels may be disposed in the display area DA. The display area DA may have various shapes, for example, circular shapes, elliptical shapes, polygonal shapes, or shapes of specific figures. It is shown in FIG. 1 that the display area DA has an approximately rectangular shape with round corners as an example.

The peripheral area PA may be disposed outside the display area DA. The peripheral area PA may be disposed to surround at least a portion of the display area DA.

Hereinafter, although an organic light-emitting display apparatus is described as an example of the display apparatus 2 according to an embodiment, the display apparatus according to the disclosure is not limited thereto. In another embodiment, the display apparatus 2 according to the disclosure may be an inorganic light-emitting display apparatus or a quantum-dot light-emitting display apparatus. For example, an emission layer of a display element provided to the display apparatus 2 may include an organic material, an inorganic material, quantum dots, an organic material and quantum dots, or an inorganic material and quantum dots.

FIG. 2 is a schematic plan view of the display apparatus 2 according to an embodiment.

Referring to FIG. 2, the display apparatus 2 may include the substrate 100. Various elements forming the display apparatus 2 are disposed on the substrate 100. The substrate 100 includes the display area DA and the peripheral area PA outside the display area DA. When a certain element is disposed in the display area DA, it means that the element is disposed in the display area DA of the substrate 100 or disposed to overlap the display area DA of the substrate 100. Likewise, when a certain element is disposed in the peripheral area PA, it means that the element is disposed in the peripheral area PA of the substrate 100 or disposed to overlap the peripheral area PA of the substrate 100.

A plurality of pixels PX may be disposed in the display area DA. Each of the pixels PX may be implemented as a light-emitting diode such as an organic light-emitting diode. Each of the pixels PX may emit, for example, red, green, blue, or white light. In the present specification, it may be understood that a term “pixel” includes a plurality of grouped “sub-pixels” to configure one pixel.

Pixel circuits driving the pixels PX may each be connected to a signal line or a voltage line configured to control turning-on/off, brightness, and the like of a light-emitting diode. For example, FIG. 2 shows a scan line SL extending in a first direction (e.g., an x axis direction), a data line DL extending in a second direction (e.g., a y axis direction), and a driving voltage line PL as a voltage line.

The peripheral area PA may be a non-display area in which images are not displayed. The peripheral area PA may surround the display area DA entirely. The peripheral area PA includes outer circuits for driving the pixels PX. For example, a first scan driver SDRV1, a second scan driver SDRV2, a data driver 20, a terminal part PAD, a driving voltage supply line 11, and a common voltage supply line 13 may be disposed in the peripheral area PA.

The first scan driver SDRV1 may be configured to apply scan signals to each of pixel circuits through the scan lines SL, the pixel circuits being configured to drive the pixels PX. The second scan driver SDRV2 may be arranged opposite the first scan driver SDRV1 with the display area DA therebetween, and be approximately parallel to the first scan driver SDRV1. Some of the pixels PX disposed in the display area DA may be electrically connected to the first scan driver SDRV1, and others may be electrically connected to the second scan driver SDRV2.

The data driver 20 may include an integrated chip (e.g., a driving chip) that drives the display apparatus 2. Although the integrated circuit may be a data driving integrated circuit configured to generate data signals, the disclosure is not limited thereto. The data driver 20 may include a plurality of terminals. The data driver 20 may be electrically connected to a printed circuit board 30 attached on one side of the display apparatus 2 through terminals. In another embodiment, the data driver 20 may be provided on the printed circuit board 30.

The terminal part PAD may be disposed on one side of the substrate 100. The terminal part PAD may be exposed by not being covered by an insulating layer, and connected to the printed circuit board 30.

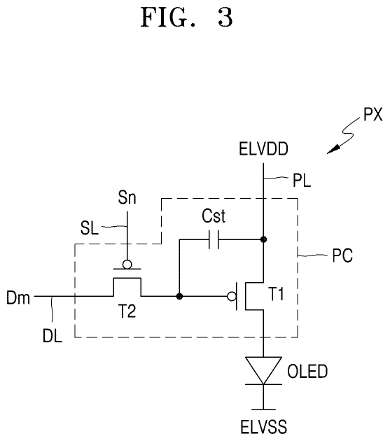

A controller (not shown) may be disposed on the printed circuit board 30. The controller may be configured to generate control signals transferred to the first scan driver SDRV1 and the second scan driver SDRV2. The controller may be configured to supply a driving voltage ELVDD (see FIG. 3) to the driving voltage supply line 11 and supply a common voltage ELVSS (see FIG. 3) to the common voltage supply line 13. The driving voltage ELVDD (see FIG. 3) may be applied to the pixel circuits of the pixels PX through the driving voltage line PL connected to the driving voltage supply line 11, and the common voltage ELVSS (see FIG. 3) may be applied to an opposite electrode of a light-emitting diode connected to the common voltage supply line 13. The driving voltage supply line 11 may extend in the first direction (e.g., the x axis direction) below the display area DA. The common voltage supply line 13 may have a loop shape having one open side to partially surround the display area DA.

The controller may generate a data signal, and the generated data signal may be transferred to the data line DL through the data driver 20. The controller may sequentially transfer data signals to the pixels PX located in the same column through the data lines DL extending in the second direction (e.g., a y direction). In addition, the controller may generate a touch driving signal transferred to each of sensor electrodes of a touch sensor layer.

FIG. 3 is a schematic circuit diagram of a light-emitting diode provided to a pixel PX of a display apparatus and a pixel circuit PC connected to the light-emitting diode according to an embodiment.

Referring to FIG. 3, the pixel circuit PC may be connected to a light-emitting diode such as an organic light-emitting diode OLED to implement light emission of the pixels PX. The pixel circuit PC may include a first transistor T1, a second transistor T2, and a storage capacitor Cst. In an embodiment, the first transistor T1 may be a driving transistor, and the second transistor T2 may be a switching transistor. The second transistor T2 is connected to the scan line SL and the data line DL, and configured to transfer a data signal Dm to the first transistor T1 according to a scan signal Sn, wherein the data signal Dm is input through the data line DL, and the scan signal Sn is input through the scan line SL.

The storage capacitor Cst may be connected to the second transistor T2 and the driving voltage line PL and configured to store a voltage corresponding to a difference between a voltage transferred from the second transistor T2 and the driving voltage ELVDD supplied to the driving voltage line PL.

The first transistor T1 may be connected to the driving voltage line PL and the storage capacitor Cst and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current.

The pixel circuit PC is not limited to the number of thin-film transistors, the number of storage capacitors, and the circuit design described with reference to FIG. 3, and the number of thin-film transistors, the number of storage capacitors, and the circuit design may be changed.

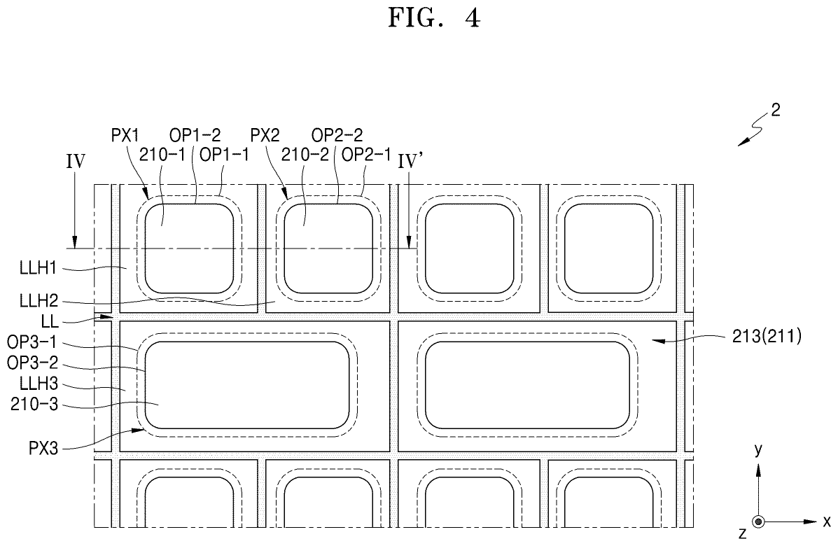

FIG. 4 is a schematic plan view of a portion of the display apparatus 2 according to an embodiment. For convenience, FIG. 4 shows a plan view of a first bank layer 211, a second bank layer 213, and a wiring layer LL.

Referring to FIG. 4, the display apparatus 2 may include a plurality of pixels PX (see FIG. 2). The plurality of pixels PX may include a first pixel PX1, a second pixel PX2, and a third pixel PX3. The first pixel PX1, the second pixel PX2, and the third pixel PX3 may be pixels configured to emit light of different colors. As an example, the first pixel PX1 may be a pixel configured to emit red light, the second pixel PX2 may be a pixel configured to emit green light, and the third pixel PX3 may be a pixel configured to emit blue light. Red light may be light in a wavelength band of about 580 nm to about 780 nm, blue light may be light in a wavelength band of about 400 nm to about 495 nm, and green light may be light in a wavelength band of about 495 nm to about 580 nm.

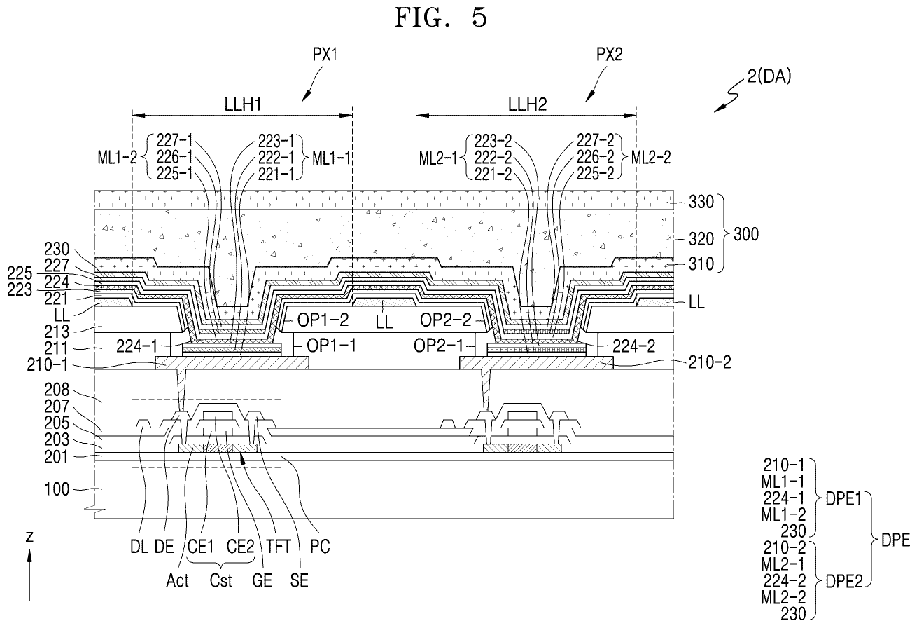

The first pixel PX1, the second pixel PX2, and the third pixel PX3 may each include a corresponding display element. As an example, the first pixel PX1 may include a first display element DPE1 (see FIG. 5) described below, the second pixel PX2 may include a second display element DPE2 (see FIG. 5) described below, and the third pixel PX3 may include a third display element (not shown).

Each of the first display element DPE1 (see FIG. 5), the second display element DPE2 (see FIG. 5), and the third display element may include a pixel electrode, an opposite electrode, and an intermediate layer between the pixel electrode and the opposite electrode.

Accordingly, the first pixel PX1 may include a first pixel electrode 210-1, the second pixel PX2 may include a second pixel electrode 210-2, and the third pixel PX3 may include a third pixel electrode 210-3. The first pixel electrode 210-1, the second pixel electrode 210-2, and the third pixel electrode 210-3 may be apart from each other. In the present specification, the expression “in a plan view” may mean a plane viewed from a z axis direction.

The first bank layer 211 and the second bank layer 213 may be disposed on the first pixel electrode 210-1, the second pixel electrode 210-2, and the third pixel electrode 210-3. As an example, the first bank layer 211 may be disposed on the first pixel electrode 210-1, the second pixel electrode 210-2, and the third pixel electrode 210-3, and the second bank layer 213 may be disposed on the first bank layer 211.

An opening above each pixel electrode may be defined in the first bank layer 211 and the second bank layer 213. In other words, an opening exposing the central portion of each pixel electrode may be defined in the first bank layer 211 and the second bank layer 213.

A first-1 opening OP1-1 above the first pixel electrode 210-1, a second-1 opening OP2-1 above the second pixel electrode 210-2, and a third-1 opening OP3-1 above the third pixel electrode 210-3 may be defined in the first bank layer 211. The first-1 opening OP1-1 may expose the central portion of the first pixel electrode 210-1. The second-1 opening OP2-1 may expose the central portion of the second pixel electrode 210-2. The third-1 opening OP3-1 may expose the central portion of the third pixel electrode 210-3.

A first-2 opening OP1-2 above the first pixel electrode 210-1, a second-2 opening OP2-2 above the second pixel electrode 210-2, and a third-2 opening OP3-2 above the third pixel electrode 210-3 may be defined in the second bank layer 213. The first-2 opening OP1-2 may expose the central portion of the first pixel electrode 210-1. The second-2 opening OP2-2 may expose the central portion of the second pixel electrode 210-2. The third-2 opening OP3-2 may expose the central portion of the third pixel electrode 210-3.

The first-1 opening OP1-1 may align with the first-2 opening OP1-2. The size of the first-1 opening OP1-1 may be greater than the size of the first-2 opening OP1-2. The second-1 opening OP2-1 may align with the second-2 opening OP2-2. The size of the second-1 opening OP2-1 may be greater than the size of the second-2 opening OP2-2. The third-1 opening OP3-1 may align with the third-2 opening OP3-2. The size of the third-1 opening OP3-1 may be greater than the size of the third-2 opening OP3-2.

Although not shown in FIG. 4, the intermediate layer may include emission layers emitting light, and the emission layers may be respectively disposed in the openings of the first bank layer 211 and the second bank layer 213. The opposite electrode may be disposed on the emission layers. A stack structure of the pixel electrode, the emission layer, and the opposite electrode may form one display element DPE (see FIG. 5).

One opening of the second bank layer 213 may correspond to one pixel and define one emission area. As an example, the first-2 opening OP1-2 may correspond to the first pixel PX1 and define an emission area of the first pixel PX1. Because the first-1 opening OP1-1 may correspond to the first pixel PX1 but the first bank layer 211 is disposed under the second bank layer 213, an emission area of the first pixel PX1 may be defined by the first-2 opening OP1-2. Similarly, the second-2 opening OP2-2 may correspond to the second pixel PX2 and define an emission area of the second pixel PX2. Because the second-1 opening OP2-1 may correspond to the second pixel PX2 but the first bank layer 211 is disposed under the second bank layer 213, an emission area of the second pixel PX2 may be defined by the second-2 opening OP2-2. Similarly, the third-2 opening OP3-2 may correspond to the third pixel PX3 and define an emission area of the third pixel PX3. Because the third-1 opening OP3-1 may correspond to the third pixel PX3 but the first bank layer 211 is disposed under the second bank layer 213, an emission area of the third pixel PX3 may be defined by the third-2 opening OP3-2.

Accordingly, the shape and area of the emission area of the first pixel PX1 may be equal to the shape and area of the first-2 opening OP1-2. Similarly, the shape and area of the emission area of the second pixel PX2 may be equal to the shape and area of the second-2 opening OP2-2. Similarly, the shape and area of the emission area of the third pixel PX3 may be equal to the shape and area of the third-2 opening OP3-2.

Each of the first-1 opening OP1-1, the first-2 opening OP1-2, the second-1 opening OP2-1, the second-2 opening OP2-2, the third-1 opening OP3-1, and the third-2 opening OP3-2 may have an approximately polygonal shape in a plan view. In other words, an emission area of the first pixel PX1, an emission area of the second pixel PX2, and an emission area of the third pixel PX3 may have an approximately polygonal shape in a plan view. FIG. 4 shows that each of the first-1 opening OP1-1, the first-2 opening OP1-2, the second-1 opening OP2-1, the second-2 opening OP2-2, the third-1 opening OP3-1, and the third-2 opening OP3-2 has an approximately quadrangular shape with round corners. However, the disclosure is not limited thereto and the opening of each of the first bank layer 211 and the second bank 213 may have various shapes.

The first-1 opening OP1-1, the first-2 opening OP1-2, the second-1 opening OP2-1, the second-2 opening OP2-2, the third-1 opening OP3-1, and the third-2 opening OP3-2 may respectively have different areas. As described above, the area of the first-1 opening OP1-1 may be greater than the area of the first-2 opening OP1-2, the area of the second-1 opening OP2-1 may be greater than the area of the second-2 opening OP2-2, and the area of the third-1 opening OP3-1 may be greater than the area of the third-2 opening OP3-2. The areas of the first-1 opening OP1-1, the second-1 opening OP2-1, and the third-1 opening OP3-1 may be different from each other. The areas of the first-2 opening OP1-2, the second-2 opening OP2-2, and the third-2 opening OP3-2 may be also different from each other. Although it is shown in FIG. 4 that the area of the first-1 opening OP1-1 is equal to the area of the second-1 opening OP2-1, and the area of the third-1 opening OP3-1 is greater than the area of the first-1 opening OP1-1 and the area of the second-1 opening OP2-1, the disclosure is not necessarily limited thereto. In addition, although it is shown in FIG. 4 that the area of the first-2 opening OP1-2 is equal to the area of the second-2 opening OP2-2, and the area of the third-2 opening OP3-2 is greater than the area of the first-2 opening OP1-2 and the area of the second-2 opening OP2-2, the disclosure is not necessarily limited thereto.

The wiring layer LL may be disposed on the second bank layer 213. The wiring layer LL may have a mesh structure surrounding the emission area of each pixel. In other words, the wiring layer LL may have a mesh structure surrounding the openings of the first bank layer 211 and the second bank layer 213. Mesh holes that align with the openings of the first bank layer 211 and the second bank layer 213 may be defined in the wiring layer LL. As an example, a first hole LLH1 that align with the first-1 opening OP1-1 and the first-2 opening OP1-2 may be defined in the wiring layer LL. Similarly, a second hole LLH2 that align with the second-1 opening OP2-1 and the second-2 opening OP2-2 may be defined in the wiring layer LL. Similarly, a third hole LLH3 that align with the third-1 opening OP3-1 and the third-2 opening OP3-2 may be defined in the wiring layer LL.

In other words, the wiring layer LL may be disposed between the openings of the second bank layer 213 and may extend in the x axis and/or y axis. Alternatively, the wiring layer LL may be disposed between the pixel electrodes and may extend in the x axis and/or y axis. As an example, a portion of the wiring layer LL may be disposed between the first pixel electrode 210-1 and the second pixel electrode 210-2 and may extend in the y axis. Another portion of the wiring layer LL may be disposed between the first pixel electrode 210-1 and the third pixel electrode 210-3 and may extend in the x axis. Another portion of the wiring layer LL may be disposed between the second pixel electrode 210-2 and the third pixel electrode 210-3 and may extend in the x axis. Respective portions of the wiring layer LL may be connected to each other to form an integrated body. Although it is shown in FIG. 4 that the wiring layer LL extends in the x axis or y axis, the disclosure is not limited to a structure in which the wiring layer LL extends in a specific direction. The wiring layer LL may include a conductive material.

FIG. 5 is a schematic cross-sectional view of a portion of the display apparatus 2 according to an embodiment. As an example, FIG. 5 is a cross-sectional view of the display apparatus 2, taken along line IV-IV′ of FIG. 4 and may be a cross-sectional view of the display area DA of the display apparatus 2.

Referring to FIGS. 4 and 5 together, the display apparatus 2 may include the substrate 100, the display element DPE, the first bank layer 211, the second bank layer 213, and an encapsulation layer 300.

Although the display element DPE may include the first display element DPE1, the second display element DPE2, and the third display element, for convenience of description, a case where the display element DPE includes the first display element DPE1 and the second display element DPE2 is mainly described below as shown in FIG. 5.

In addition, the first display element DPE1 and the second display element DPE2 are electrically connected to the pixel circuit PC, and thus, light emission may be controlled. In this case, because the structures of the pixel circuits PC electrically connected to the first display element DPE1 and the second display element DPE2, respectively, are identical to each other, one pixel circuit PC is mainly described below.

The display apparatus 2 may include the substrate 100. The substrate 100 may include various flexible or bendable materials. As an example, the substrate 100 may include glass, metal, or a polymer resin. In addition, the substrate 100 may include polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including the polymer resin, and a barrier layer including an inorganic material (such as silicon oxide (SiO₂), silicon nitride (SiNₓ), and/or silicon oxynitride (SiON), and the like) therebetween. However, various modifications may be made.

The display element DPE and the pixel circuit PC may be disposed on the substrate 100. The pixel circuit PC may be electrically connected to the display element DPE. As an example, the first pixel PX1 and the second pixel PX2 may be disposed on the substrate 100. Each of the first pixel PX1 and the second pixel PX2 may include the display element DPE. The display element DPE may be the first display element DPE1 or the second display element DPE2. That is, the first pixel PX1 may include the first display element DPE1, and the second pixel PX2 may include the second display element DPE2.

The pixel circuit PC may include a plurality of thin-film transistors TFT and a storage capacitor Cst. For convenience of illustration, FIG. 5 shows one thin-film transistor TFT, and the thin-film transistor TFT may correspond to the first transistor T1 (see FIG. 3) described above.

A buffer layer 201 may be disposed between the thin-film transistor TFT and the substrate 100, wherein the buffer layer 201 may include an inorganic material such as silicon oxide (SiO₂), silicon nitride (SiNₓ), and/or silicon oxynitride (SiON). The buffer layer 201 may increase a smoothness of the upper surface of the substrate 100 or prevent or at least reduce impurities from penetrating a semiconductor layer Act of the thin-film transistor TFT.

As shown in FIG. 5, the thin-film transistor TFT may include the semiconductor layer Act including amorphous silicon, polycrystalline silicon, an organic semiconductor material, or an oxide semiconductor material. The thin-film transistor TFT may include a gate electrode GE, a source electrode SE, and/or a drain electrode DE. The gate electrode GE may include various conductive materials and have various layered structures, and include, for example, a Mo layer and an Al layer. Alternatively, the gate electrode GE may include a TiNₓ layer, an Al layer, and/or a Ti layer. The source electrode SE and the drain electrode DE may also include various conductive materials and various layered structures, and may include, for example, a Ti layer, an Al layer, and/or a Cu layer.

To secure insulation between the semiconductor layer Act and the gate electrode GE, a gate insulating layer 203 may be disposed between the semiconductor layer Act and the gate electrode GE, wherein the gate insulating layer 203 includes an inorganic material such as silicon oxide (SiO₂), silicon nitride (SiNₓ), and/or silicon oxynitride (SiON). Although it is shown in FIG. 5 that the gate insulating layer 203 has a shape corresponding to the entire surface of the substrate 100, and has a structure in which contact holes are formed in preset portions thereof, the disclosure is not limited thereto. As an example, the gate insulating layer 203 may be patterned to have the same shape as that of the gate electrode GE.

A first interlayer insulating layer 205 may be disposed on the gate electrode GE, wherein the first interlayer insulating layer 205 includes an inorganic material such as silicon oxide (SiO₂), silicon nitride (SiNₓ), and/or silicon oxynitride (SiON). The first interlayer insulating layer 205 may include a single layer or a multi-layered structure including the above materials. The insulating layer including the inorganic material may be formed by chemical vapor deposition (CVD) or atomic layer deposition (ALD). This is also applicable to embodiments below and modifications thereof.

The storage capacitor Cst may include a first electrode CE1 and a second electrode CE2 overlapping each other with the first interlayer insulating layer 205 therebetween. The storage capacitor Cst may overlap the thin-film transistor TFT. With regard to this, although it is shown in FIG. 5 that the gate electrode GE of the thin-film transistor TFT serves as the first electrode CE1 of the storage capacitor Cst, the embodiment is not limited thereto. As an example, the storage capacitor Cst may not overlap the thin-film transistor TFT. The second electrode CE2 of the storage capacitor Cst may include a conductive material including molybdenum (Mo), aluminum (Al), copper (Cu), and titanium (Ti) and have a single-layered structure or a multi-layered structure including the above materials.

A second interlayer insulating layer 207 may be disposed on the second electrode CE2 of the storage capacitor Cst, wherein the second interlayer insulating layer 207 includes an inorganic material such as silicon oxide (SiO₂), silicon nitride (SiNₓ), and/or silicon oxynitride (SiON). The second interlayer insulating layer 207 may include a single layer or a multi-layered structure including the above materials.

The source electrode SE and the drain electrode DE may be disposed on the second interlayer insulating layer 207. The data line DL may be disposed on the same layer as the source electrode SE and the drain electrode DE and may include the same material as a material of the source electrode SE and the drain electrode DE. The source electrode SE, the drain electrode DE, and the data line DL may include a conductive material. The source electrode SE and the drain electrode DE may each include a conductive material including molybdenum (Mo), aluminum (Al), copper (Cu), and titanium (Ti) and include a single layer or a multi-layered structure including the above materials. As an example, the source electrode SE, the drain electrode DE, and the data line DL may each include a multi-layered structure of Ti/Al/Ti.

However, the embodiment is not limited thereto. As an example, the thin-film transistor TFT may include one of the source electrode SE and the drain electrode DE, or include neither of the source electrode SE and the drain electrode DE. As an example, a thin-film transistor TFT may not include a drain electrode DE, and another thin-film transistor TFT connected to the thin-film transistor TFT may not include a source electrode SE, and semiconductor layers Act of the two thin-film transistors TFT may be connected to each other. This connection structure may provide the same effect as when one thin-film transistor TFT has a source electrode SE and another thin-film transistor TFT has a drain electrode DE, the source electrode SE of the one thin-film transistor TFT is connected to the drain electrode DE of the other thin-film transistor TFT.

A planarization layer 208 may be disposed to cover the thin-film transistor TFT and the storage capacitor Cst. The planarization layer 208 may include an organic insulating material. As an example, the planarization layer 208 may include a photoresist, benzocyclobutene, polyimide, hexamethyldisiloxane, polymethylmethacrylate, polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof. Although not shown in FIG. 5, a third interlayer insulating layer (not shown) may be further disposed under the planarization layer 208. The third interlayer insulating layer may include an inorganic insulating layer such as silicon oxide (SiO₂), silicon nitride (SiNₓ), and silicon oxynitride (SiON).

The first display element DPE1 and the second display element DPE2 may be disposed to be apart from each other on the planarization layer 208. As an example, the first display element DPE1 and the second display element DPE2 adjacent to each other in the first direction (e.g., the x axis direction) may be disposed on the planarization layer 208. The first display element DPE1 and the second display element DPE2 may respectively emit light of different colors. As an example, the first display element DPE1 may emit red, blue, or green light. The second display element DPE2 may emit red, blue, or green light.

The first display element DPE1 may include the first pixel electrode 210-1, a first-1 intermediate layer ML1-1, a first charge generation layer 224-1, a first-2 intermediate layer ML1-2, and the opposite electrode 230. The first-1 intermediate layer ML1-1 may be disposed on the first pixel electrode 210-1, the first charge generation layer 224-1 may be disposed on the first-1 intermediate layer ML1-1, the first-2 intermediate layer ML1-2 may be disposed on the first charge generation layer 224-1, and the opposite electrode 230 may be disposed on the first-2 intermediate layer ML1-2.

The second display element DPE2 may include the second pixel electrode 210-2, a second-1 intermediate layer ML2-1, a second charge generation layer 224-2, a second-2 intermediate layer ML2-2, and the opposite electrode 230. The second-1 intermediate layer ML2-1 may be disposed on the second pixel electrode 210-2, the second charge generation layer 224-2 may be disposed on the second-1 intermediate layer ML2-1, the second-2 intermediate layer ML2-2 may be disposed on the second charge generation layer 224-2, and the opposite electrode 230 may be disposed on the second-2 intermediate layer ML2-2.

The first pixel electrode 210-1 and the second pixel electrode 210-2 respectively provided to the first display element DPE1 and the second display element DPE2 may be patterned for each pixel. The opposite electrode 230 of the first display element DPE1 and the second display element DPE2 may extend continuously over the first display element DPE1 and the second display element DPE2.

The first pixel electrode 210-1 and the second pixel electrode 210-2 may be disposed to be apart from each other over the substrate 100. As an example, the first pixel electrode 210-1 and the second pixel electrode 210-2 may be disposed to be apart from each other on the planarization layer 208.

The first pixel electrode 210-1 and the second pixel electrode 210-2 include a light-transmissive conductive layer and a reflective layer, wherein the light-transmissive conductive layer includes a light-transmissive conductive oxide such as indium tin oxide (ITO), indium oxide (In₂O₃) or indium zinc oxide (IZO), and the reflective layer includes metal such as Al or Ag. As an example, the first pixel electrode 210-1 and the second pixel electrode 210-2 may have a three-layered structure of ITO/Ag/ITO.

The first pixel electrode 210-1 and the second pixel electrode 210-2 may be electrically connected to the thin-film transistor TFT by being in contact with one of the source electrode SE and the drain electrode DE as shown in FIG. 5. For example, each of the first pixel electrode 210-1 and the second pixel electrode 210-2 may be in contact with one of the source electrode SE and the drain electrode DE through a contact hole formed in the planarization layer 208.

The first bank layer 211 may be disposed on the substrate 100. As an example, the first bank layer 211 may be disposed on the planarization layer 208, the first pixel electrode 210-1, and the second pixel electrode 210-2.

The first bank layer 211 may cover the edge (or the edge region) of the first pixel electrode 210-1. In other words, the first bank layer 211 may be opened to expose the central portion of the first pixel electrode 210-1. As an example, the first bank layer 211 may have the first-1 opening OP1-1 above the first pixel electrode 210-1. In other words, the first-1 opening OP1-1 above the first pixel electrode 210-1 may be defined in the first bank layer 211.

The first bank layer 211 may cover the edge (or the edge region) of the second pixel electrode 210-2. In other words, the first bank layer 211 may be opened to expose the central portion of the second pixel electrode 210-2. For example, the first bank layer 211 may have the second-1 opening OP2-1 above the second pixel electrode 210-2. In other words, the second-1 opening OP2-1 above the second pixel electrode 210-2 may be defined in the first bank layer 211.

The second bank layer 213 may be disposed on the substrate 100. As an example, the second bank layer 213 may be disposed on the first bank layer 211.

The second bank layer 213 may be opened to expose the central portion of the first pixel electrode 210-1. For example, the second bank layer 213 may have the first-2 opening OP1-2 above the first pixel electrode 210-1. In other words, the first-2 opening OP1-2 above the first pixel electrode 210-1 may be defined in the second bank layer 213. The first-2 opening OP1-2 may be aligned with the first-1 opening OP1-1 of the first bank layer 211.

The second bank layer 213 may be opened to expose the central portion of the second pixel electrode 210-2. As an example, the second bank layer 213 may have the second-2 opening OP2-2 above the second pixel electrode 210-2. In other words, the second-2 opening OP2-2 above the second pixel electrode 210-2 may be defined in the second bank layer 213. The second-2 opening OP2-2 may be aligned with the second-1 opening OP2-1 of the first bank layer 211.

Respective openings of the second bank layer 213 may be less than corresponding openings of the first bank layer 211 that are aligned with the openings. As an example, the size of the first-2 opening OP1-2 may be less than the size of the first-1 opening OP1-1. Similarly, the size of the second-2 opening OP2-2 may be less than the size of the second-1 opening OP2-1.

In other words, the first bank layer 211 and the second bank layer 213 may form an undercut structure in a region above each pixel electrode. As an example, a portion of the second bank layer 213 defining the first-2 opening OP1-2 may extend beyond the edge of the first bank layer 211 defining the first-1 opening OP1-1. Accordingly, a portion of the second bank layer 213 may protrude beyond the edge of the first bank layer 211 and form an undercut structure in a region above the first pixel electrode 210-1. Similarly, a portion of the second bank layer 213 defining the second-2 opening OP2-2 may extend beyond the edge of the first bank layer 211 defining the second-1 opening OP2-1. Accordingly, a portion of the second bank layer 213 may protrude beyond the edge of the first bank layer 211 and form an undercut structure in a region above the second pixel electrode 210-2.

The first bank layer 211 and the second bank layer 213 may include an inorganic material (e.g., an inorganic insulating material). As an example, the first bank layer 211 and the second bank layer 213 may include at least one selected from among silicon oxide (SiO₂), silicon nitride (SiNₓ), and/or silicon oxynitride (SiON).

The first bank layer 211 and the second bank layer 213 may respectively include materials having different selectivities. As an example, the first bank layer 211 may include silicon nitride (SiNₓ), and the second bank layer 213 may include silicon oxide (SiO₂). Through this, during the same process, the openings (e.g., the first-1 opening OP1-1 and the second-1 opening OP2-1) of the first bank 211, and the openings (e.g., the first-2 opening OP1-2 and the second-2 opening OP2-2) of the second bank 213 may be formed in different sizes.

The wiring layer LL may be disposed on the substrate 100. As an example, the wiring layer LL may be disposed on the second bank layer 213. A portion of the wiring layer LL may be disposed between the first pixel electrode 210-1 and the second pixel electrode 210-2. In other words, a portion of the wiring layer LL may be disposed between the first-1 opening OP1-1 and the second-1 opening OP2-1. Alternatively, a portion of the wiring layer LL may be disposed between the first-2 opening OP1-2 and the second-2 opening OP2-2. As described above, in a plan view, the wiring layer LL may be disposed to surround each of the first pixel electrode 210-1 and the second pixel electrode 210-2.

In other words, the wiring layer LL may include holes above the first pixel electrode 210-1 or the second pixel electrode 210-2. As an example, the wiring layer LL may include a first hole LLH1 above the first pixel electrode 210-1, the first-1 opening OP1-1, and the first-2 opening OP1-2. Similarly, the wiring layer LL may include a second hole LLH2 above the second pixel electrode 210-2, the second-1 opening OP2-1, and the second-2 opening OP2-2.

Each of the first display element DPE1 and the second display element DPE2 may include a tandem structure including a plurality of emission layers. Each of the first display element DPE1 and the second display element DPE2 may improve color purity and a light emission efficiency by having the structure in which the plurality of emission layers are stacked.

A first common layer 221 may be disposed on the second bank layer 213 and the wiring layer LL, a second common layer 223 may be disposed on the first common layer 213, a charge generation layer 224 may be disposed on the second common layer 223, a third common layer 225 may be disposed on the charge generation layer 224, a fourth common layer 227 may be disposed on the third common layer 225, and the opposite electrode 230 may be disposed on the fourth common layer 227.

A portion of the first common layer 221 disposed on the first pixel electrode 210-1 is denoted by a first-1 common layer 221-1, and a portion of the first common layer 221 disposed on the second pixel electrode 210-2 is denoted by a second-1 common layer 221-2.

A portion of the second common layer 223 disposed on the first-1 common layer 221-1 is denoted by a first-2 common layer 223-1, and a portion of the second common layer 223 disposed on the second-1 common layer 221-2 is denoted by a second-2 common layer 223-2. A first-1 emission layer 222-1 may be disposed between the first-1 common layer 221-1 and the first-2 common layer 223-1, and a second-1 emission layer 222-2 may be disposed between the second-1 common layer 221-2 and the second-2 common layer 223-2.

A portion of the charge generation layer 224 disposed on the first-2 common layer 223-1 is denoted by the first charge generation layer 224-1, and a portion of the charge generation layer 224 disposed on the second-2 common layer 223-2 is denoted by a second charge generation layer 224-2.

A portion of the third common layer 225 disposed on the first charge generation layer 224-1 is denoted by a first-3 common layer 225-1, and a portion of the third common layer 225 disposed on the second charge generation layer 224-2 is denoted by a second-3 common layer 225-2.

A portion of the fourth common layer 227 disposed on the first-3 common layer 225-1 is denoted by a first-4 common layer 227-1, and a portion of the fourth common layer 227 disposed on the second-3 common layer 225-2 is denoted by a second-4 common layer 227-2. A first-2 emission layer 226-1 may be disposed between the first-3 common layer 225-1 and the first-4 common layer 227-1, and a second-2 emission layer 226-2 may be disposed between the second-3 common layer 225-2 and the second-4 common layer 227-2.

The first-1 common layer 221-1, the first-1 emission layer 222-1, and the first-2 common layer 223-1 are denoted by the first-1 intermediate layer ML1-1, and the first-3 common layer 225-1, the first-2 emission layer 226-1, and the first-4 common layer 227-1 are denoted by the first-2 intermediate layer ML1-2. In other words, the first-2 intermediate layer ML1-2 may include the first-1 common layer 221-1, the first-1 emission layer 222-1, and the first-2 common layer 223-1, and the first-2 intermediate layer ML1-2 may include the first-3 common layer 225-1, the first-2 emission layer 226-1, and the first-4 common layer 227-1. The first display element DPE1 may include the first pixel electrode 210-1, a first-1 intermediate layer ML1-1, a first charge generation layer 224-1, a first-2 intermediate layer ML1-2, and the opposite electrode 230.

The second-1 common layer 221-2, the second-1 emission layer 222-2, and the second-2 common layer 223-2 are denoted by the second-1 intermediate layer ML2-1, and the second-3 common layer 225-2, the second-2 emission layer 226-2, and the second-4 common layer 227-2 are denoted by the second-2 intermediate layer ML2-2. In other words, the second-1 intermediate layer ML2-1 may include the second-1 common layer 221-2, the second-1 emission layer 222-2, and the second-2 common layer 223-2, and the second-2 intermediate layer ML2-2 may include the second-3 common layer 225-2, the second-2 emission layer 226-2, and the second-4 common layer 227-2. The second display element DPE2 may include the second pixel electrode 210-2, the second-1 intermediate layer ML2-1, the second charge generation layer 224-2, the second-2 intermediate layer ML2-2, and the opposite electrode 230.

The first-1 emission layer 222-1 and the second-1 emission layer 222-2 may be respectively patterned for the first display element DPE1 and the second display element DPE2 and provided individually. In addition, the first-2 emission layer 226-1 and the second-2 emission layer 226-2 may be respectively patterned for the first display element DPE1 and the second display element DPE2 and provided individually.

The first-1 emission layer 222-1 and the first-2 emission layer 226-1 may emit light of the same color. As an example, each of the first-1 emission layer 222-1 and the first-2 emission layer 226-1 may emit red, blue, or green light. The second-1 emission layer 222-2 and the second-2 emission layer 226-2 may emit light of the same color. As an example, each of the second-1 emission layer 222-2 and the second-2 emission layer 226-2 may emit red, blue, or green light.

The charge generation layer 224 may be commonly provided over the first display element DPE1 and the second display element DPE2. The charge generation layer (CGL) 224 may supply charge to the first-1 intermediate layer ML1-1, the first-2 intermediate layer ML1-2, the second-1 intermediate layer ML2-1, the second-2 intermediate layer ML2-2. Accordingly, the charge generation layer 224 may even more increase the light emission efficiency of each of the first display element DPE1 and the second display element DPE2 having the structure in which the plurality of emission layers are stacked.

The charge generation layer 224 may include an n-type charge generation layer nCGL for supplying electrons to the first-1 intermediate layer ML1-1 and the second-1 intermediate layer ML2-1. In addition, the charge generation layer 224 may include a p-type charge generation layer pCGL for supplying holes to the first-2 intermediate layer ML1-2 and the second-2 intermediate layer ML2-2.

The n-type charge generation layer may include n-type dopant materials and n-type host materials. The n-type dopant material may be a metal of a Group 1 and a Group 2 of the periodic table, an organic material capable of injecting electrons, or a mixture thereof. For example, the n-type dopant material may be either an alkali metal or an alkaline earth metal. That is, although the n-type charge generation layer may include an organic layer doped with an alkali metal such as lithium (Li), sodium (Na), potassium (K), or cesium (Cs), or an alkaline earth metal such as magnesium (Mg), strontium (Sr), barium (Ba), or radium (Ra), the disclosure is not limited thereto. Although an n-type host material may include a material capable of transferring electrons, for example, at least one of Alq3(tris(8-hydroxyquinolino)aluminum), Liq(8-hydroxyquinolinolato-lithium), PBD(2-(4-biphenylyl)-5-(4-tert-butylphenyl)-1,3,4oxadiazole), TAZ(3-(4-biphenyl)4-phenyl-5-tert-butylphenyl-1,2,4-triazole), spiro-PBD, and BAlq(bis(2-methyl-8-quinolinolate)-4-(phenylphenolato)aluminium), SAlq, TPBi(2,2′,2-(1,3,5-benzinetriyl)-tris(1-phenyl-1-H-benzimidazole), oxadiazole, triazole, phenanthroline, benzoxazole, and benzthiazole, the disclosure is not limited thereto.

The p-type charge generation layer may include p-type dopant materials and p-type host materials. The p-type dopant material may include, but is not limited to, a metal oxide, an organic material such as tetrafluoro-tetracyanoquinodimethane (F4-TCNQ), HAT-CN (hexaazatriphenylene-hexacarbonitrile), hexaazatriphenylene, or a metal material such as V₂O₅, MoOₓ, and WO₃. Although the p-type host material include a material capable of transferring holes, for example, a material including at least one of NPD (N,N-dinaphthyl-N,N′-diphenyl benzidine)(N,N′-bis(naphthalene-1-yl)-N,N′-bis(phenyl)-2,2′-dimethylbenzidine), TPD (N,N′-bis-(3-methylphenyl)-N,N′-bis-(phenyl)-benzidine), and MTDATA (4,4′,4-Tris(N-3-methylphenyl-N-phenyl-amino)-triphenylamine), the disclosure is not limited thereto.

The first common layer 221 may include a single layer or a multi-layer. As an example, the first common layer 221 is a hole transport layer (HTL), which has a single-layered structure, and may include polyethylene dihydroxythiophene (PEDOT: poly-(3,4)-ethylene-dihydroxy thiophene) or polyaniline (PANI: polyaniline). Alternatively, the first common layer 221 may include a hole injection layer (HIL) and an HTL.

The second common layer 223 may be omitted and be optional. The second common layer 223 may include a single layer or a multi-layer. The second common layer 223 may include an electron transport layer (ETL) and/or an electron injection layer (EIL).

The third common layer 225 may include a single layer or a multi-layer. As an example, the third common layer 225 is an HTL, which has a single-layered structure, and may include polyethylene dihydroxythiophene (PEDOT: poly-(3,4)-ethylene-dihydroxy thiophene) or polyaniline (PANI: polyaniline). Alternatively, the third common layer 225 may include a hole injection layer (HIL) and an HTL.

The fourth common layer 227 is optional and may be omitted. The fourth common layer 227 may include a single layer or a multi-layer. The fourth common layer 227 may include an electron transport layer (ETL) and/or an electron injection layer (EIL).

The first-1 intermediate layer ML1-1 may be disposed in the first-1 opening OP1-1 of the first bank layer 211. That is, the first-1 common layer 221-1, the first-1 emission layer 222-1, and the first-2 common layer 223-1 may be disposed in the first-1 opening OP1-1 of the first bank layer 211. The first-1 common layer 221-1 may be disconnected from the remaining portion of the first common layer 221. The first-2 common layer 223-1 may be disconnected from the remaining portion of the second common layer 223.

The second-1 intermediate layer ML2-1 may be disposed in the second-1 opening OP2-1 of the first bank layer 211. That is, the second-1 common layer 221-2, the second-1 emission layer 222-2, and the second-2 common layer 223-2 may be disposed in the second-1 opening OP2-1 of the first bank layer 211. The second-1 common layer 221-2 may be disconnected from the remaining portion of the first common layer 221. The second-2 common layer 223-2 may be disconnected from the remaining portion of the second common layer 223.

The first-1 common layer 221-1 and the second-1 common layer 221-2 may be disconnected from each other, the first-1 emission layer 222-1 and the second-1 emission layer 222-2 may be individually patterned, the first-2 common layer 223-1 and the second-2 common layer 223-2 may be disconnected from each other, and the first-1 intermediate layer ML1-1 and the second-1 intermediate layer ML2-1 may be apart and disconnected from each other.

The opposite electrode 230 may be integrally formed on the fourth common layer 227. The opposite electrode 230 and the wiring layer LL may be insulated from each other by the first common layer 221, the second common layer 223, the charge generation layer 224, the third common layer 225, and the fourth common layer 227 therebetween. In another embodiment, unlike FIG. 5, the opposite electrode 230 and the wiring layer LL may be connected to each other. As an example, the opposite electrode 230 and the wiring layer LL may be connected to each other through a contact hole formed in the first common layer 221, the second common layer 223, the charge generation layer 224, the third common layer 225, and the fourth common layer 227.

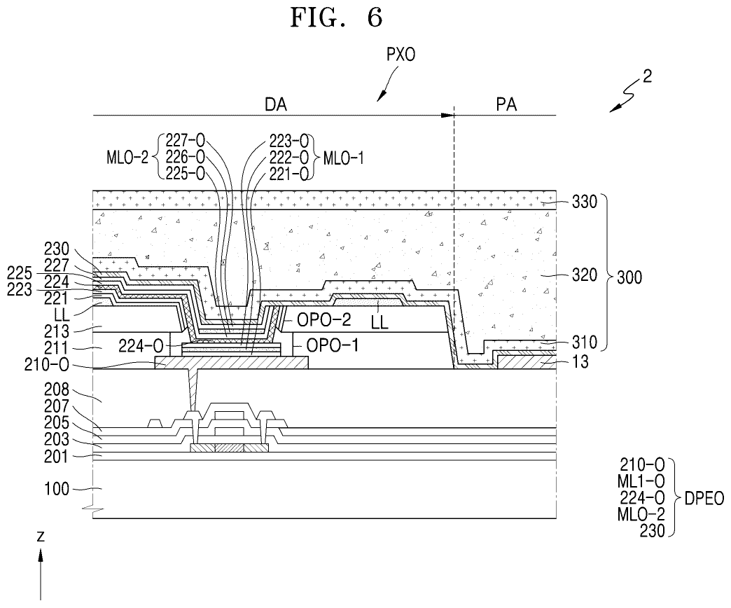

In an embodiment, the wiring layer LL may be electrically connected to the common voltage supply line 13 (see FIG. 2). As an example, as described with reference to FIG. 6, the wiring layer LL may be connected to the opposite electrode 230 in a region adjacent to the peripheral area PA (see FIG. 6), and the opposite electrode 230 may be connected to the common voltage supply line 13 (see FIG. 6) in the peripheral area PA (see FIG. 6). Accordingly, the common voltage ELVSS (see FIG. 3) may be applied to the wiring layer LL.

The wiring layer LL and the charge generation layer 224 overlapping the wiring layer LL may serve as a capacitor. A capacitance may be formed between the wiring layer LL and the charge generation layer 224. In this structure, the wiring layer LL may absorb a lateral leakage current flowing through the charge generation layer 224. That is, the wiring layer LL may reduce a leakage current formed between the first charge generation layer 224-1 and the second charge generation layer 224-2. Accordingly, the durability and quality of the display apparatus 2 may be improved.

The encapsulation layer 300 may be disposed on the display element DPE. As an example, the encapsulation layer 300 may be disposed on the opposite electrode 230. The encapsulation layer 300 may include at least one inorganic layer and at least one organic layer. As an example, the encapsulation layer 300 may include a first inorganic encapsulation layer 310, an organic encapsulation layer 320, and a second inorganic encapsulation layer 330 that are sequentially stacked. However, the structure of the encapsulation layer 300 is not limited thereto and may have various configuration.

The first inorganic encapsulation layer 310 and/or the second inorganic encapsulation layer 330 may include at least one selected from among silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂).

The organic encapsulating layer (320) may include at least one material selected from among an acryl-based resin layer, a methacryl-based resin layer, polyisoprene, a vinyl-based resin layer, an epoxy-based resin layer, a urethane-based resin layer, a cellulose-based resin layer, and a perylene-based resin layer.

In an embodiment, various functional layers such as a polarizing layer, a color filter layer, and a touchscreen layer may be further disposed on the encapsulation layer 300.

FIG. 6 is a schematic cross-sectional view of a portion of the display apparatus 2 according to an embodiment. For example, FIG. 6 may be a cross-sectional view of the display apparatus 2, taken near the border between the display area DA and the peripheral area PA.

Referring to FIGS. 5 and 6, a pixel disposed in the outermost portion of the display area DA is denoted by an outer pixel PXO. As an example, the outer pixel PXO may be a pixel immediately adjacent to the peripheral area PA. A substantial structure of the outer pixel PXO may be the same as that of the first pixel PX1 or the second pixel PX2 described above, and the pixel is denoted by the outer pixel PXO to distinguish its location.

The outer pixel PXO may include an outer display element DPEO. The outer display element DPEO may include an outer pixel electrode 210-O, a first outer intermediate layer MLO-1, a outer charge generation layer 224-O, a second outer intermediate layer MLO-2, and the opposite electrode 230. The first outer intermediate layer MLO-1 may include a first outer common layer 221-O, a first outer emission layer 222-O, and a second outer common layer 223-O. The second outer intermediate layer MLO-2 may include a third outer common layer 225-O, a second outer emission layer 226-O, and a fourth outer common layer 227-O.

A portion of the first common layer 221 overlapping the outer pixel electrode 210-O may be denoted by the first outer common layer 221-O. A portion of the second common layer 223 overlapping the outer pixel electrode 210-O may be denoted by the second outer common layer 223-O. A portion of the third common layer 225 overlapping the outer pixel electrode 210-O may be denoted by the third outer common layer 225-O. A portion of the fourth common layer 227 overlapping the outer pixel electrode 210-O may be denoted by the fourth outer common layer 227-O. A portion of the charge generation layer 224 overlapping the outer pixel electrode 210-O may be denoted by the outer charge generation layer 224-O.

The first outer emission layer 222-O and the second outer emission layer 226-O may be patterned to overlap the outer pixel electrode 210-O.

The first bank layer 211 may include a first outer opening OPO-1 overlapping the outer pixel electrode 210-O. The second bank layer 213 may include a second outer opening OPO-2 overlapping the outer pixel electrode 210-O. The size of the first outer opening OPO-1 may be greater than the size of the second outer opening OPO-2.

The first outer intermediate layer MLO-1 may be disposed in the first outer opening OPO-1 of the first bank layer 211. That is, the first outer common layer 221-O, the first outer emission layer 222-O, and the second outer common layer 223-O may be disposed in the first outer opening OPO-1 of the first bank layer 211. The first outer common layer 221-O may be disconnected from the remaining portion of the first common layer 221. The second outer common layer 223-O may be disconnected from the remaining portion of the second common layer 223.

The wiring layer LL may be disposed on the second bank layer 213. A portion of the wiring layer LL may be adjacent to the border between the display area DA and the peripheral area PA. In a region adjacent to the border between the display area DA and the peripheral area PA, the first common layer 221, the second common layer 223, the charge generation layer 224, the third common layer 225, and the fourth common layer 227 may not be disposed on the second bank layer 213. Accordingly, the opposite electrode 230 and the wiring layer LL may be in direct contact with each other near the border between the display area DA and the peripheral area PA. Through this, the opposite electrode 230 may be electrically connected to the wiring layer LL.

The first bank layer 211 and the second bank layer 213 may be disposed in the display area DA. In other words, the first bank layer 211 and the second bank layer 213 may not be disposed in the peripheral area PA. The common voltage supply line 13 may be disposed in the peripheral area PA. The common voltage supply line 13 may be disposed on the same layer as the first pixel electrode 210-1, the second pixel electrode 210-2, and the outer pixel electrode 210-O. The opposite electrode 230 may extend over the peripheral area PA. In the peripheral area PA, the opposite electrode 230 may be in direct contact with the common voltage supply line 13 and electrically connected to the common voltage supply line 13. The common voltage supply line 13, the opposite electrode 230, and the wiring layer LL may be electrically connected to each other. Accordingly, the common voltage ELVSS (see FIG. 3) may be applied to the opposite electrode 230 and the wiring layer LL.

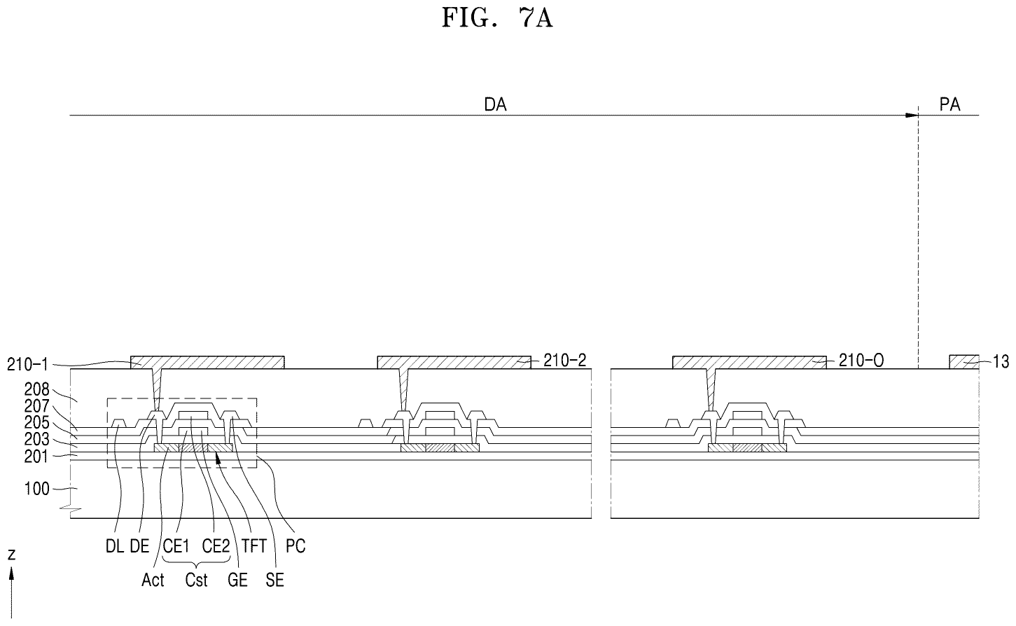

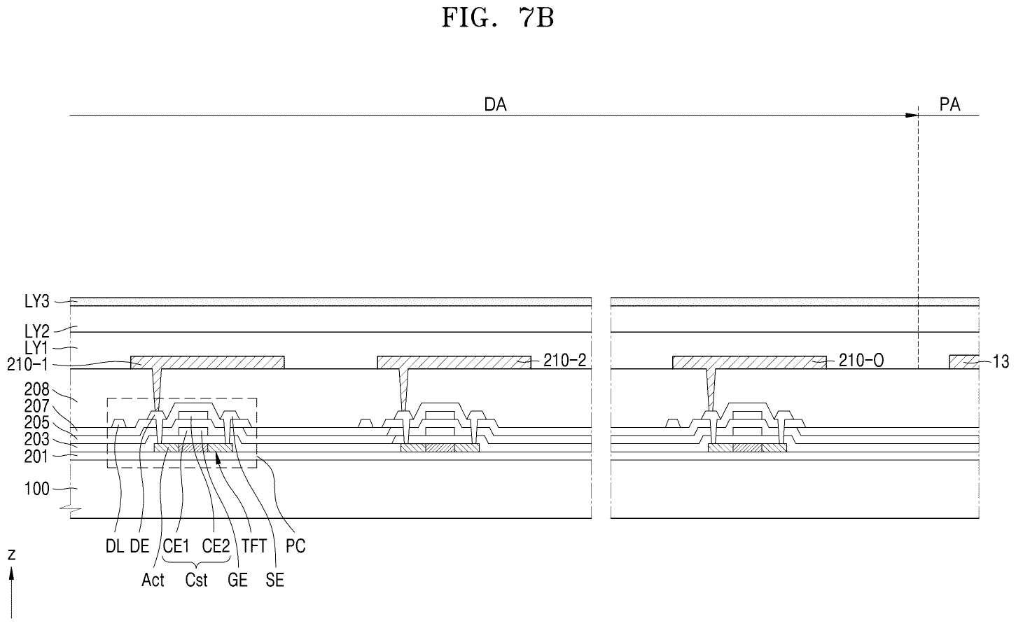

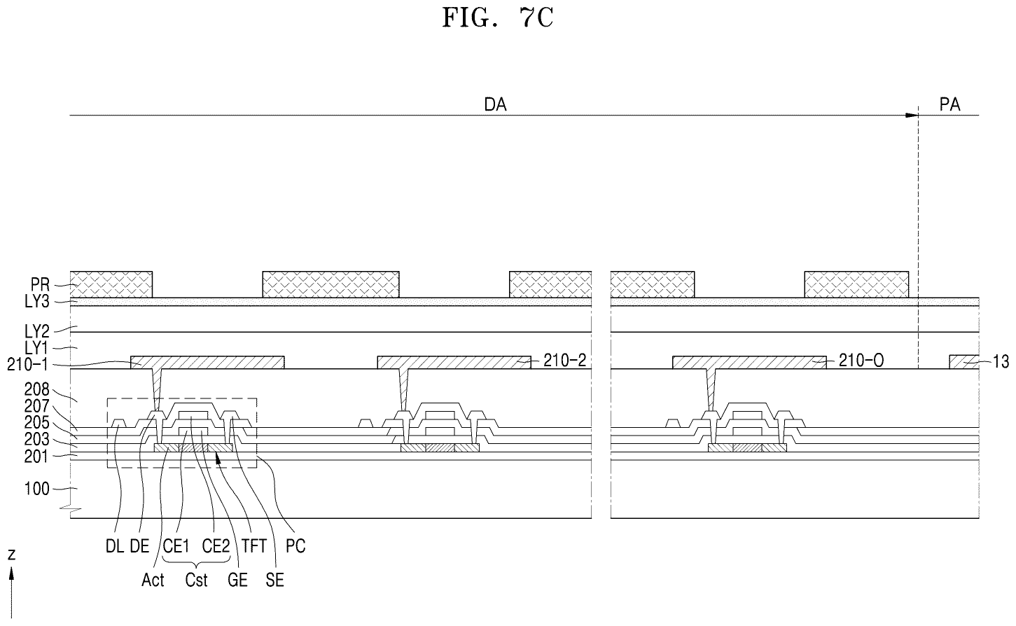

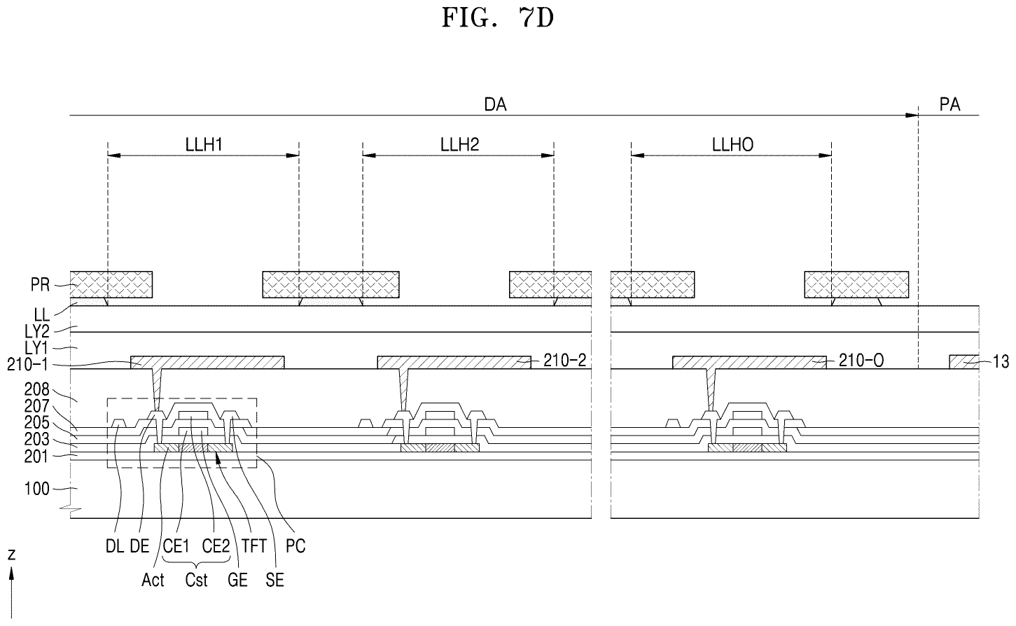

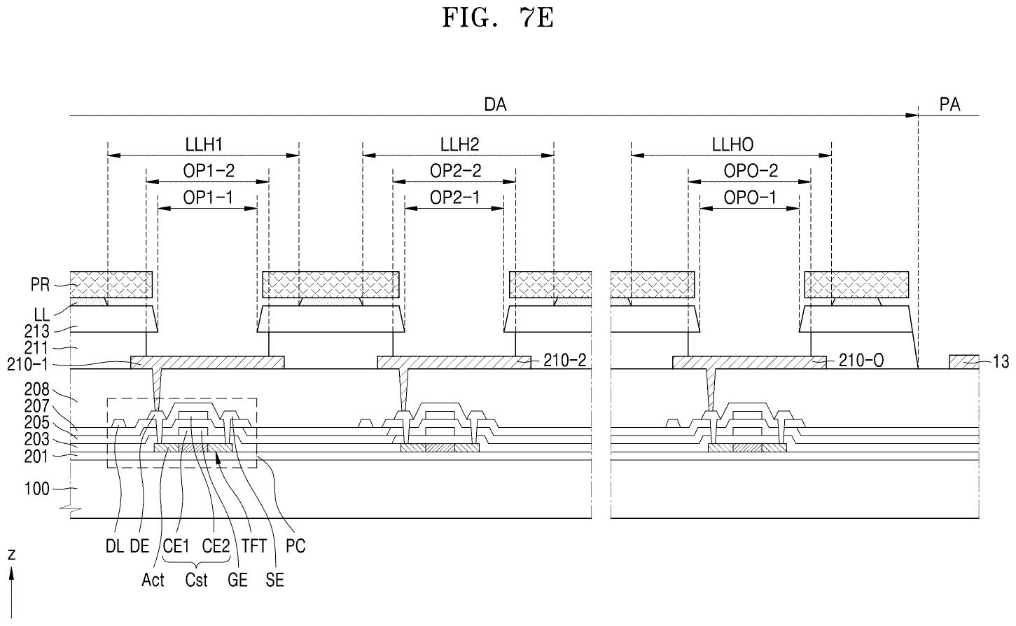

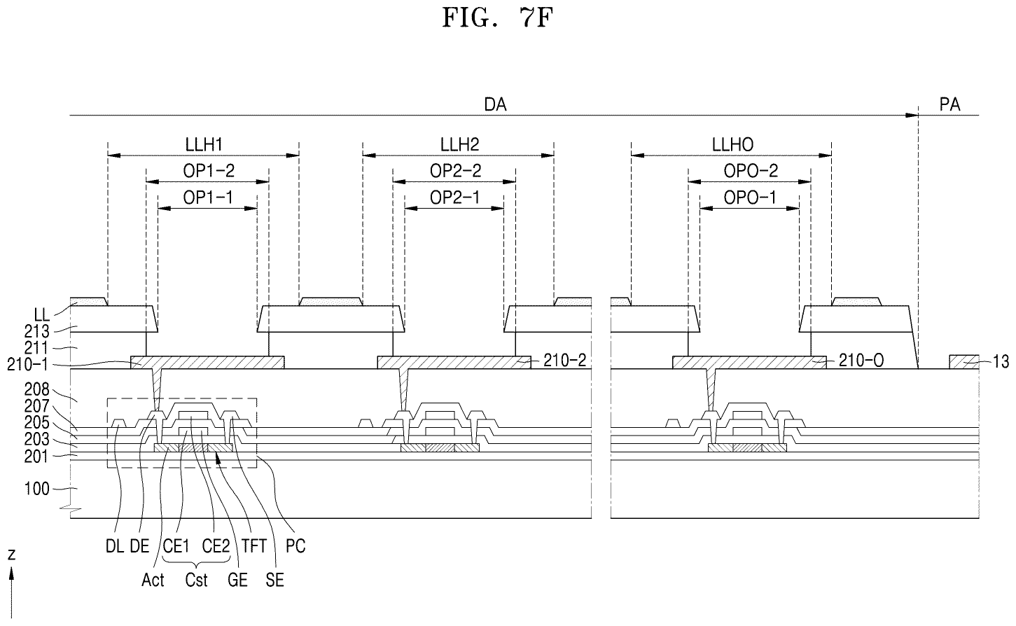

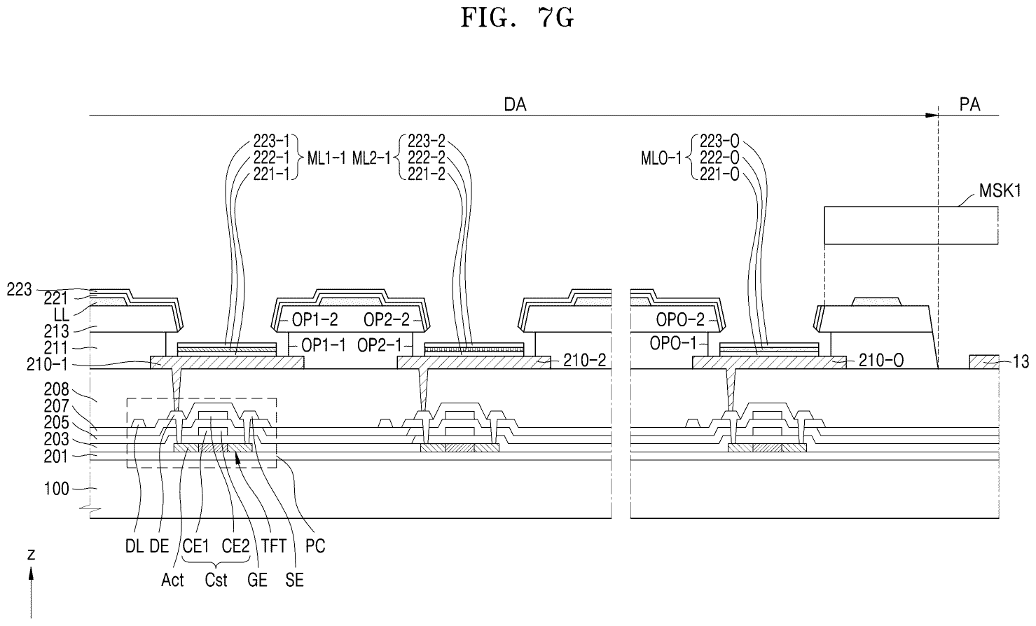

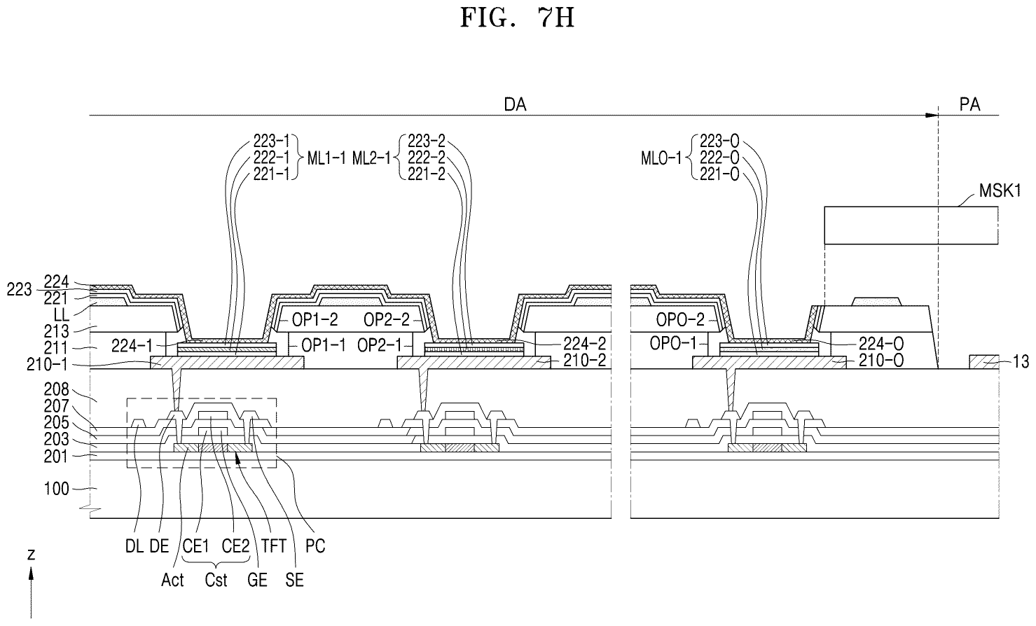

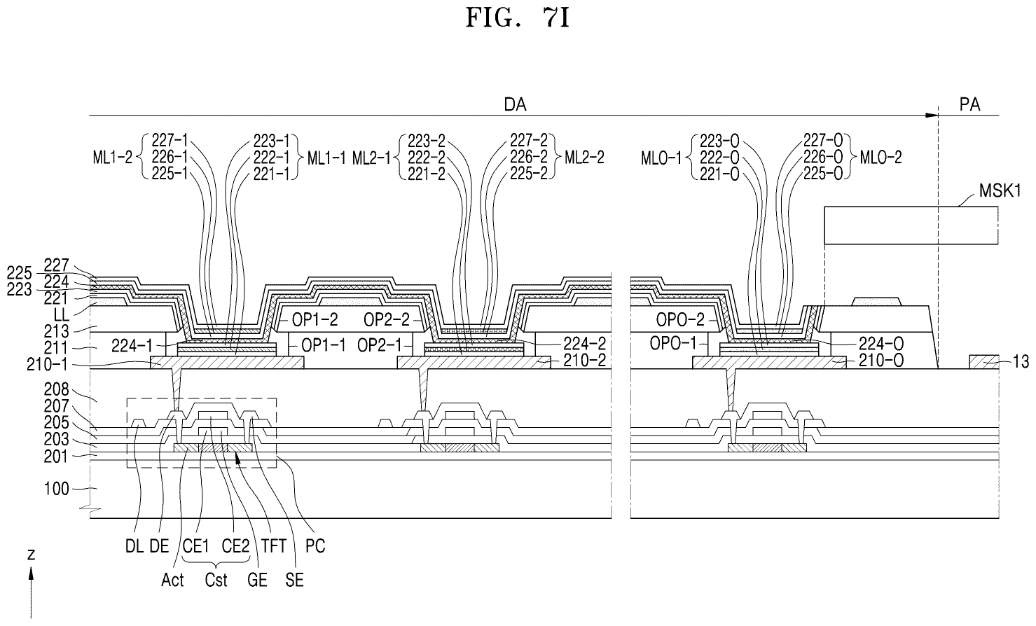

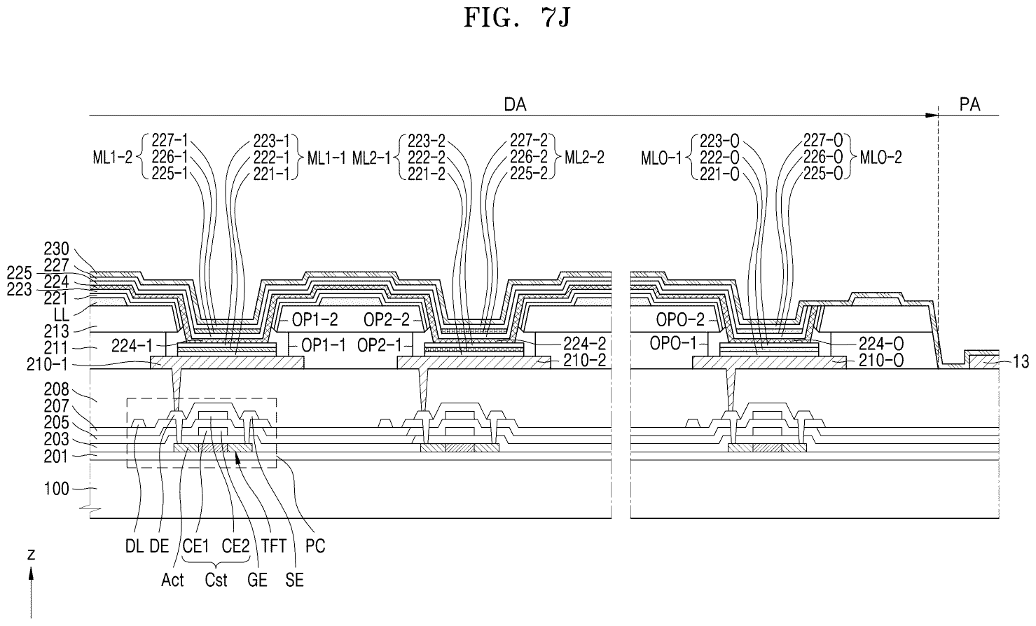

FIGS. 7A to 7J are schematic cross-sectional views showing processes of a method of manufacturing a display apparatus according to an embodiment.

In FIGS. 7A to 19, the same reference numerals as those of FIGS. 1 to 6 denote the same members, and thus, repeated descriptions thereof are omitted.

Referring to FIGS. 7A to 7J, the display area DA and the peripheral area PA may be defined in the substrate 100. The pixel circuit PC may be disposed on the substrate 10. The pixel circuit PC may include the thin-film transistor TFT and the storage capacitor Cst. The thin-film transistor TFT may include the semiconductor layer Act, the gate electrode GE, the source electrode SE, and/or the drain electrode DE. The buffer layer 201 may be disposed between the thin-film transistor TFT and the substrate 100. The gate insulating layer 203 may be disposed between the semiconductor layer Act and the gate electrode GE. The first interlayer insulating layer 205 may be disposed on the gate electrode GE. The storage capacitor Cst may include the first electrode CE1 and the second electrode CE2 overlapping each other with the first interlayer insulating layer 205 therebetween. The source electrode SE and the drain electrode DE may be disposed on the second interlayer insulating layer 207. The data line DL may be disposed on the same layer as the source electrode SE and the drain electrode DE. The planarization layer 208 may be disposed to cover the thin-film transistor TFT and the storage capacitor Cst.

Referring to FIG. 7A, the first pixel electrode 210-1, the second pixel electrode 210-2, the outer pixel electrode 210-O, and the common voltage supply line 13 may be disposed on the planarization layer 208. The outer pixel electrode 210-O may be a pixel electrode adjacent to the border between the display area DA and the peripheral area PA. The first pixel electrode 210-1, the second pixel electrode 210-2, the outer pixel electrode 210-O, and the common voltage supply line 13 may be individually patterned. Accordingly, the first pixel electrode 210-1, the second pixel electrode 210-2, the outer pixel electrode 210-O, and the common voltage supply line 13 may be apart from each other. In an embodiment, the first pixel electrode 210-1, the second pixel electrode 210-2, the outer pixel electrode 210-O, and the common voltage supply line 13 may include the same material. The first pixel electrode 210-1, the second pixel electrode 210-2, the outer pixel electrode 210-O, and the common voltage supply line 13 may include a conductive material. For example, the first pixel electrode 210-1, the second pixel electrode 210-2, the outer pixel electrode 210-O, and/or the common voltage supply line 13 may include a metal or conductive oxide.

Referring to FIG. 7B, a first layer LY1, a second layer LY2, and a third layer LY3 may be sequentially disposed on the first pixel electrode 210-1, the second pixel electrode 210-2, the outer pixel electrode 210-O, and the common voltage supply line 13. As an example, the first layer LY1 may be disposed to cover the first pixel electrode 210-1, the second pixel electrode 210-2, the outer pixel electrode 210-O, and the common voltage supply line 13, the second layer LY2 may be disposed on the first layer LY1 to cover the first layer LY1, and the third layer LY3 may be disposed on the second layer LY2 to cover the second layer LY2. The first layer LY1 may include the same material as a material of the first bank layer 211 described above with reference to FIG. 5. The second layer LY2 may include the same material as a material of the second bank layer 213 described above with reference to FIG. 5. That is, the first layer LY1 and the second layer LY2 may respectively include inorganic insulating materials having different selectivities. The third layer LY3 may include the same material as a material of the wiring layer LL described above with reference to FIG. 5. That is, the third layer LY3 may include a conductive material.

Referring to FIG. 7C, a photoresist PR may be disposed on the third layer LY3. The photoresist PR may include openings above the first pixel electrode 210-1, the second pixel electrode 210-2, and the outer pixel electrode 210-O. The photoresist PR may be disposed in the display area DA and may not be disposed in the peripheral area PA. That is, the photoresist PR may not be disposed on the common voltage supply line 13.

Referring to FIGS. 7C and 7D, the third layer LY3 may be patterned as the wiring layer LL. In an embodiment, a portion of the third layer LY3 may be etched using the photoresist PR as a mask. The etching may include wet etching. The first hole LLH1, the second hole LLH2, and an outer hole LLHO may be formed by etching a portion of the third layer LY3. The first hole LLH1 may be positioned above the first pixel electrode 210-1, the second hole LLH2 may be positioned above the second pixel electrode 210-2, and the outer hole LLHO may be positioned above the outer pixel electrode 210-O. In the case where the etching includes wet etching, due to the characteristics of wet etching, a portion of the third layer LY3 disposed under the photoresist PR may also be etched. That is, the sizes of the first hole LLH1, the second hole LLH2, and the outer hole LLHO may be greater than the sizes of the openings of the photoresist PR aligned with the first hole LLH1, the second hole LLH2, and the outer hole LLHO, respectively.

A remaining portion of the third layer LY3 after etching the third layer LY3 may be understood as the wiring layer LL. In an embodiment, the third layer LY3 may be patterned such that the wiring layer LL has a planar shape described with reference to FIG. 4. For example, the third layer LY3 may be patterned such that the wiring layer LL has a mesh structure including the first hole LLH1, the second hole LLH2, and the outer hole LLHO.

Because the photoresist PR is not disposed on the third layer LY3 in the peripheral area PA, the third layer LY3 may be removed in the peripheral area PA.

In an embodiment, the present process may be understood as a first patterning operation.

Referring to FIGS. 7D and 7E, the first layer LY1 may be patterned as the first bank layer 211, and the second layer LY2 may be patterned as the second bank layer 213. In an embodiment, a portion of the first layer LY1 and a portion of the second layer LY2 may be etched using the photoresist PR as a mask. The etching may include dry etching. The first-1 opening OP1-1, the second-1 opening OP2-1, and the first outer opening OPO-1 may be formed by etching a portion of the first layer LY1. The first-1 opening OP1-1 may be above the first pixel electrode 210-1, the second-1 opening OP2-1 may be above the second pixel electrode 210-2, and the first outer opening OPO-1 may be above the outer pixel electrode 210-O. The first-2 opening OP1-2, the second-2 opening OP2-2, and the second outer opening OPO-2 may be formed by etching a portion of the second layer LY2. The first-2 opening OP1-2 may be above the first pixel electrode 210-1, the second-2 opening OP2-2 may be above the second pixel electrode 210-2, and the second outer opening OPO-2 may be above the outer pixel electrode 210-O.

A remaining portion of the first layer LY1 after etching the first layer LY1 may be understood as the first bank layer 211, and a remaining portion of the second layer LY2 after etching the second layer LY2 may be understood as the second bank layer 213. In an embodiment, the first layer LY1 and the second layer LY2 may be patterned such that the planar shapes of the openings (e.g., the first-1 opening OP1-1, the second-1 opening OP2-1, and the first outer opening OPO-1) of the first bank 211, and the openings (e.g., the first-2 opening OP1-2, the second-2 opening OP2-2, and the second outer opening OPO-2) of the second bank 213 have the shapes described with reference to FIG. 4.

The first layer LY1 and the second layer LY2 may respectively include materials having different selectivities. Accordingly, in the same etching process, the first layer LY1 and the second layer LY2 may be etched to different degrees. In an embodiment, a selectivity of the first layer LY1 may be greater than a selectivity of the second layer LY2. Accordingly, the first layer LY1 may be etched more than the second layer LY2. Accordingly, the size of the openings formed in the first layer LY1 may be greater than the size of the openings formed in the second layer LY2. As an example, the size of the first-1 opening OP1-1 may be greater than the size of the first-2 opening OP1-2, the size of the second-1 opening OP2-1 may be greater than the size of the second-2 opening OP2-2, and the size of the first outer opening OPO-1 may be greater than the size of the second outer opening OPO-2. In other words, the first layer LY1 and the second layer LY2 may be patterned such that the first bank layer 211 and the second bank layer 213 have an undercut structure in a region above the respective pixel electrodes (e.g., the first pixel electrode 210-1, the second pixel electrode 210-2, and the outer pixel electrode 210-O). In this case, because the first layer LY1 and the second layer LY2 respectively include materials having different selectivities, an additional sacrificial layer or mask does not need to be used.

Because the photoresist PR is not disposed on the second layer LY2 in the peripheral area PA, the second layer LY2 and the first layer LY1 may be removed in the peripheral area PA.

In an embodiment, the present process may be understood as a second patterning operation.

Referring to FIGS. 7E and 7F, the photoresist PR may be removed.

Referring to FIG. 7G, the first-1 intermediate layer ML1-1, the second-1 intermediate layer ML2-1, and the first outer intermediate layer MLO-1 may be disposed.

First, the first common layer 221 may be formed. A portion of the first common layer 221 may be disposed on the first pixel electrode 210-1 in the first-1 opening OP1-1, and this portion may be understood as the first-1 common layer 221-1. Similarly, a portion of the first common layer 221 may be disposed on the second pixel electrode 210-2 in the second-1 opening OP2-1, and this portion may be understood as the second-1 common layer 221-2. Similarly, a portion of the first common layer 221 may be disposed on the outer pixel electrode 210-O in the first outer opening OPO-1, and this portion may be understood as the first outer common layer 221-O.

The first-1 common layer 221-1, the second-1 common layer 221-2, and the first outer common layer 221-O may be disconnected from the remaining portion of the first common layer 221 due to the undercut structure of the first bank layer 211 and the second bank layer 213. Accordingly, the first-1 common layer 221-1, the second-1 common layer 221-2, and the first outer common layer 221-O may be apart from each other.

The first-1 emission layer 222-1 may be disposed on the first-1 common layer 221-1. That is, the first-1 emission layer 222-1 may be disposed in the first-1 opening OP1-1. The second-1 emission layer 222-2 may be disposed on the second-1 common layer 221-2. That is, the second-1 emission layer 222-2 may be disposed in the second-1 opening OP2-1. The first outer emission layer 222-O may be disposed on the first outer common layer 221-O. That is, the first outer emission layer 222-O may be disposed in the first outer opening OPO-1.

Each of the first-1 emission layer 222-1, the second-1 emission layer 222-2, and the first outer emission layer 222-O may be individually formed through patterning.

Next, the second common layer 223 may be formed. A portion of the second common layer 223 may be disposed on the first-1 emission layer 222-1 in the first-1 opening OP1-1, and this portion may be understood as the first-2 common layer 223-1. Similarly, a portion of the second common layer 223 may be disposed on the second-1 emission layer 222-2 in the second-1 opening OP2-1, and this portion may be understood as the second-2 common layer 223-2. Similarly, a portion of the second common layer 223 may be disposed on the first outer emission layer 222-O in the first outer opening OPO-1, and this portion may be understood as the second outer common layer 223-O.

The first-2 common layer 223-1, the second-2 common layer 223-2, and the second outer common layer 223-O may be disconnected from the remaining portion of the second common layer 223 due to the undercut structure of the first bank layer 211 and the second bank layer 213. Accordingly, the first-2 common layer 223-1, the second-2 common layer 223-2, and the second outer common layer 223-O may be apart from each other.

The first-1 intermediate layer ML1-1 may include the first-1 common layer 221-1, the first-1 emission layer 222-1, and the first-2 common layer 223-1. The second-1 intermediate layer ML2-1 may include the second-1 common layer 221-2, the second-1 emission layer 222-2, and the second-2 common layer 223-2. The first outer intermediate layer MLO-1 may include the first outer common layer 221-O, the first outer emission layer 222-O, and the second outer common layer 223-O. Because the first-1 common layer 221-1, the second-1 common layer 221-2, and the first outer common layer 221-O may be formed to be apart from each other, the first-1 emission layer, the second-1 emission layer 222-2, and the first outer emission layer 222-O may be individually patterned, and the first-2 common layer 223-1, the second-2 common layer 223-2, and the second outer common layer 223-O may be formed to be apart from each other, the first-1 intermediate layer ML1-1, the second-1 intermediate layer ML2-1, and the first outer intermediate layer MLO-1 may be apart and disconnected from each other.

In other words, the first common layer 221 and the second common layer 223 may be disconnected in a region above the first-2 opening OP1-2, disconnected in a region above the second-2 opening OP2-2, and disconnected in a region above the second outer opening OPO-2.

In the present process, a mask MSK may be disposed to screen the peripheral area PA and the second bank layer 213 and the wiring layer LL adjacent to the peripheral area PA. Accordingly, the first common layer 221 and/or the second common layer 223 may not be disposed in the peripheral area PA and on the second bank layer 213 and the wiring layer LL adjacent to the peripheral area PA.

Referring to FIG. 7H, the charge generation layer 224 may be disposed.

In an embodiment, the charge generation layer 224 may be continuously disposed over the display area DA or disconnected in a partial region. FIG. 7H shows a case where the charge generation layer 224 is continuously disposed over the display area DA. A portion of the charge generation layer 224 disposed on the first-1 intermediate layer ML1-1 may be understood as the first charge generation layer 224-1. A portion of the charge generation layer 224 disposed on the second-1 intermediate layer ML2-1 may be understood as the second charge generation layer 224-2. A portion of the charge generation layer 224 disposed on the first outer intermediate layer MLO-1 may be understood as the outer charge generation layer 224-O. In an embodiment, the charge generation layer 224 may be continuously formed despite the undercut structure of the first bank layer 211 and the second bank layer 213. In another embodiment, the charge generation layer 224 may be disconnected due to the undercut structure of the first bank layer 211 and the second bank layer 213.

In the present process, the mask MSK may be still disposed. Accordingly, the charge generation layer 224 may not be disposed in the peripheral area PA and on the second bank layer 213 and the wiring layer LL adjacent to the peripheral area PA.

Referring to FIG. 7I, the first-2 intermediate layer ML1-2, the second-2 intermediate layer ML2-2, and the second outer intermediate layer MLO-2 may be disposed.

First, the third common layer 225 may be formed. A portion of the third common layer 225 may be disposed on the first charge generation layer 224-1, and this portion may be understood as the first-3 common layer 225-1. Similarly, a portion of the third common layer 225 may be disposed on the second charge generation layer 224-2, and this portion may be understood as the second-3 common layer 225-2. Similarly, a portion of the first common layer 221 may be disposed on the outer charge generation layer 224-O, and this portion may be understood as the third common layer 225-O.

The third charge generation layer 225 may be formed continuously despite the undercut structure of the first bank layer 211 and the second bank layer 213. That is, the first-3 common layer 225-1, the second-5 common layer 225-2, and the third outer common layer 225-O may be connected to each other, as depicted in FIG. 7I. In another embodiment, the third common layer 225 may be disconnected due to the undercut structure of the first bank layer 211 and the second bank layer 213, and in this case, the first-3 common layer 225-1, the second-3 common layer 225-2, and the third outer common layer 225-O may be disconnected from each other.

The first-2 emission layer 226-1 may be disposed on the first-3 common layer 225-1. The second-2 emission layer 226-2 may be disposed on the second-3 common layer 225-2. The second outer emission layer 226-O may be disposed on the third outer common layer 225-O.

Each of the first-2 emission layer 226-1, the second-2 emission layer 226-2, and the second outer emission layer 226-O may be individually formed through patterning.

Next, the fourth common layer 227 may be formed. A portion of the fourth common layer 227 may be disposed on the first-2 emission layer 226-1, and this portion may be understood as the first-4 common layer 227-1. Similarly, a portion of the fourth common layer 227 may be disposed on the second-2 emission layer 226-2, and this portion may be understood as the second-4 common layer 227-2. Similarly, a portion of the fourth common layer 227 may be disposed on the second outer emission layer 226-O, and this portion may be understood as the fourth outer common layer 227-O.

The fourth common layer 227 may be formed continuously without being disconnected despite the undercut structure of the first bank layer 211 and the second bank layer 213. That is, the first-4 common layer 227-1, the second-4 common layer 227-2, and the fourth outer common layer 227-O may be connected to each other. In another embodiment, the fourth common layer 227 may be disconnected due to the undercut structure of the first bank layer 211 and the second bank layer 213, and in this case, the first-4 common layer 227-1, the second-4 common layer 227-2, and the fourth outer common layer 227-O may be apart and disconnected from each other.

The first-2 intermediate layer ML1-2 may include the first-3 common layer 225-1, the first-2 emission layer 226-1, and the first-4 common layer 227-1. The second-2 intermediate layer ML2-2 may include the second-3 common layer 225-2, the second-2 emission layer 226-2, and the second-4 common layer 227-2. The second outer intermediate layer MLO-2 may include the third outer common layer 225-O, the second outer emission layer 226-O, and the fourth outer common layer 227-O.

In the present process, the mask MSK may be disposed to screen the peripheral area PA and the second bank layer 213 and the wiring layer LL adjacent to the peripheral area PA. Accordingly, the third common layer 225 and/or the fourth common layer 227 may not be disposed in the peripheral area PA and on the second bank layer 213 and the wiring layer LL adjacent to the peripheral area PA.

Referring to FIG. 7J, the opposite electrode 230 may be disposed. The opposite electrode 230 may be continuously disposed over the display area DA and the peripheral area PA. Accordingly, the opposite electrode 230 may be also disposed on the first-2 intermediate layer ML1-2, the second-2 intermediate layer ML2-2, and the second outer intermediate layer MLO-2. A portion of the wiring layer LL adjacent to the peripheral area PA, and not covered by the first common layer 221, the second common layer 223, the third common layer 225, and the fourth common layer 227 may be covered by the opposite electrode 230. Accordingly, the opposite electrode 230 may be in direct contact with the wiring layer LL near the border between the display area DA and the peripheral area PA.

The opposite electrode 230 may extend to the peripheral area PA. The opposite electrode 230 may cover the common voltage supply line 13 in the peripheral area PA. Accordingly, the opposite electrode 230 may be electrically connected to the common voltage supply line 13 by being in direct contact with the common voltage supply line 13 in the peripheral area PA. Through this, the common voltage supply line 13, the opposite electrode 230, and the wiring layer LL may be electrically connected to each other.

According to embodiments, because a phenomenon that a leakage current flows through the display apparatus is reduced, the quality of the display apparatus may be improved.

According to embodiments, the number of deposition masks used to form a structure (e.g., an undercut structure and a wiring layer) of a display apparatus that is capable of decreasing current leakage may be reduced.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate;
a first pixel electrode and a second electrode arranged apart from each other over the substrate;
a first bank layer disposed on the first pixel electrode and the second electrode and including a first-1 opening above the first pixel electrode, and a second-1 opening above the second pixel electrode;
a second bank layer disposed on the first bank layer and including a first-2 opening above the first pixel electrode, and a second-2 opening above the second pixel electrode; and
a wiring layer disposed on the second bank layer and including a portion disposed between the first pixel electrode and the second pixel electrode,
wherein the first bank layer includes a first inorganic insulating material and the second bank layer includes a second inorganic insulating material having a different selectivity from the first inorganic insulating material.

2. The display apparatus of claim 1, further comprising:
a first-1 intermediate layer disposed on the first pixel electrode;
a first charge generation layer disposed on the first-1 intermediate layer;
a first-2 intermediate layer disposed on the first charge generation layer;
a second-1 intermediate layer disposed on the second pixel electrode;
a second charge generation layer disposed on the second-1 intermediate layer;
a second-2 intermediate layer disposed on the second charge generation layer; and
an opposite electrode disposed on the first-2 intermediate layer and the second-2 intermediate layer.

3. The display apparatus of claim 2, wherein the wiring layer is electrically connected to the opposite electrode.

4. The display apparatus of claim 3, wherein the opposite electrode is electrically connected to a common voltage supply line.

5. The display apparatus of claim 3, wherein the display apparatus includes a display area and a peripheral area, and the wiring layer is in direct contact with the opposite electrode, near a border between the display area and the peripheral area, in the display area.

6. The display apparatus of claim 2, wherein the first-1 intermediate layer and the second-1 intermediate layer are separated from each other.

7. The display apparatus of claim 1, wherein, in a plan view, the wiring layer has a mesh structure including a hole above the first pixel electrode, and a hole above the second pixel electrode.

8. The display apparatus of claim 1, wherein a size of the first-1 opening is greater than a size of the first-2 opening, and a size of the second-1 opening is greater than a size of the second-2 opening.

9. The display apparatus of claim 1, wherein the first bank layer and the second bank layer form an undercut structure where the second bank layer extends beyond the edge of the first bank layer.

10. An electronic apparatus including a display apparatus and a housing accommodating the display apparatus, wherein the display apparatus includes:
a substrate;
a first pixel electrode and a second electrode arranged apart from each other over the substrate;
a first bank layer disposed on the first pixel electrode and the second electrode and including a first-1 opening above the first pixel electrode, and a second-1 opening above the second pixel electrode;
a second bank layer disposed on the first bank layer and including a first-2 opening above the first pixel electrode, and a second-2 opening above the second pixel electrode; and
a wiring layer disposed on the second bank layer and including a portion disposed between the first pixel electrode and the second pixel electrode, wherein the first bank layer includes a first inorganic insulating material and the second bank layer includes a second inorganic insulating material having a different selectivity from the first inorganic insulating material.

11. A method of manufacturing a display apparatus, the method comprising:
providing a substrate including a display area and a peripheral area;
arranging a first pixel electrode and a second pixel electrode in the display area;
sequentially arranging a first layer, a second layer and a third layer on the first pixel electrode and the second pixel electrode; and
patterning the first layer, the second layer, and the third layer to form a first bank layer, a second bank layer, and a wiring layer, respectively, to expose a central portion of the first pixel electrode and a central portion of the second pixel electrode,
wherein the first layer includes a first inorganic insulating material, the second layer includes a second inorganic insulating material having a different selectivity from the first inorganic insulating material, and the third layer includes a conductive material.

12. The method of claim 11, wherein the patterning includes:
arranging a photoresist on the third layer;
patterning the third layer; and
patterning the first layer and the second layer after the patterning of the third layer.

13. The method of claim 12, wherein the patterning of the third layer includes forming the wiring layer having a mesh structure including a hole above the first pixel electrode and a hole above the second pixel electrode.

14. The method of claim 12, wherein the patterning of the first layer and the second layer includes:
patterning the first layer such that the first bank layer has a first-1 opening above the first pixel electrode and a second-1 opening above the second pixel electrode; and
patterning the second layer such that the second bank layer has a first-2 opening above the first pixel electrode and a second-2 opening above the second pixel electrode.

15. The method of claim 14, wherein a size of the first-1 opening is greater than a size of the first-2 opening, and a size of the second-1 opening is greater than a size of the second-2 opening.

16. The method of claim 12, wherein the patterning of the first layer and the second layer includes removing a portion of the first layer and a portion of the second layer disposed in the peripheral area.

17. The method of claim 11, further comprising:
arranging a first-1 intermediate layer on the first pixel electrode;
arranging a second-1 intermediate layer on the second pixel electrode;
arranging a charge generation layer on the first-1 intermediate layer and the second-1 intermediate layer;
arranging a first-2 intermediate layer on the charge generation layer and on the first pixel electrode; and
arranging a second-2 intermediate layer on the charge generation layer and on the second pixel electrode.

18. The method of claim 17, wherein the first-1 intermediate layer and the second-1 intermediate layer are separated from each other.

19. The method of claim 17, further comprising arranging an opposite electrode on the first-2 intermediate layer and the second-2 intermediate layer,
wherein the wiring layer is in direct contact with the opposite electrode, near a border between the display area and the peripheral area, within the display area.

20. The method of claim 19, wherein the opposite electrode is connected to a common voltage supply line in the peripheral area.
